(19) United States
(12) Patent Application Publication
(10) Pub. No.: US 2010/0051993 A1
(43) Pub. Date: Mar. 4, 2010

(54) LIGHT EMITTING APPARATUS AND MANUFACTURING METHOD THEREOF

(75) Inventors: Satoru SHIMODA, Tokyo (JP); Tomoyuki SHIRASAKI, Tokyo (JP); Takashi KIDU, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: CASIO COMPUTER CO., LTD., Tokyo (JP)

(21) Appl. No.: 12/548,542

(22) Filed: Aug. 27, 2009

(30) Foreign Application Priority Data
Sep. 3, 2008 (JP) 2008-225721
Sep. 8, 2008 (JP) 2008-229626

(51) Int. Cl. H01L 33/00; H01L 21/00

(52) U.S. Cl. 257/98; 438/29; 257/E33.001; 257/E21.001

(57) ABSTRACT

Disclosed is a light emitting apparatus including: a first electrode; at least one carrier transporting layer on the first electrode; a second electrode on the carrier transporting layer; a partition wall formed on an upper face side of a substrate the partition wall including an opening to be communicated with the first electrode; and a light emitting protecting layer mediating between the partition wall and the carrier transporting layer.

### BACKGROUND OF THE INVENTION

1. Field of the Invention

The present invention relates to a light emitting apparatus and manufacturing method thereof.

2. Description of the Related Art

In recent years, there is known as a display device of an electronic device such as cellular phones an application of an Electro Luminescent (EL) light emitting panel where a plurality of EL light emitting elements, which are self light emitting elements, are arranged in a matrix shape.

For example, Japanese Patent Application Laid-Open Publication No. 2002-91343 describes a technique where as for an EL light emitting element, a light emitting layer is formed on a first electrode exposed to an opening formed in an insulating layer composed of, for example polyimide and a second electrode is laminated on the light emitting layer, and on the panel, each opening is a light emitting portion corresponding to a pixel and the light emitting area is structured by a plurality of EL light emitting elements.

However, in the EL light emitting panel of the above described technique, among the plurality of EL light emitting elements which compose the light emitting area of the EL light emitting panel, it has come to be known that there are partial areas where the EL light emitting elements do not emit light.

### SUMMARY OF THE INVENTION

The present invention has been made in consideration of the above situation, and one of the main objects is to provide a light emitting apparatus with excellent light emitting properties and a manufacturing method of such light emitting apparatus.

In order to achieve any one of the above advantages, according to an aspect of the present invention, there is provided a light emitting apparatus including:

a first electrode;

at least one carrier transporting layer on the first electrode;

a second electrode on the carrier transporting layer;

a partition wall formed on an upper face side of a substrate, the partition wall including an opening to be communicated with the first electrode; and

a light emitting protecting layer mediating between the partition wall and the carrier transporting layer.

According to another aspect of the present invention, there is provided a manufacturing method of a light emitting apparatus including a first electrode, at least one carrier transporting layer on the first electrode, and a second electrode on the carrier transporting layer, the method including:

forming a partition wall on an upper face side of a substrate, the partition wall including an opening to be communicated with the first electrode;

forming a light emitting protecting layer to cover at least the partition wall so as to seal a factor of preventing light emission caused by the partition wall; and

forming the carrier transporting layer to cover the first electrode and the light emitting protecting layer

According to another aspect of the present invention, there is provided a manufacturing method of a light emitting apparatus including a light emitting element including a first electrode, at least one carrier transporting layer on the first electrode, and a second electrode on the carrier transporting layer, the method including:

forming a partition wall on a substrate, the partition wall including an opening to be communicated with the first electrode;

cleaning a surface of the partition wall and a surface of the first electrode to remove a factor of preventing light emission which occurs in the step of forming the partition wall; and

forming the carrier transporting layer to cover the first electrode and the partition wall.

According to another aspect of the present invention, there is provided a light emitting apparatus manufactured by the manufacturing method of the light emitting apparatus.

### BRIEF DESCRIPTION OF THE DRAWINGS

The present invention and the above-described objects, features and advantages thereof will become more fully understood from the following detailed description with the accompanying drawings and wherein;

FIG. 1 is a planer view showing an arrangement structure of a pixel of an EL panel;

FIG. 2 is a planer view showing a schematic structure of the EL panel;

FIG. 3 is a circuit diagram showing a circuit corresponding to one pixel of the EL panel;

FIG. 4 is a planar view showing one pixel of the EL panel;

FIG. 5 is a cross sectional view showing a plane viewed along arrows V-V shown in FIG. 4;

FIG. 6 is a cross sectional view showing a plane viewed along arrows VI-VI shown in FIG. 4;

FIG. 7 is a cross sectional view showing a thin film transistor and interlayer insulating film formed on an upper face side of a substrate;

FIG. 8 is a cross sectional view showing a material layer which is to be a bank formed on the upper face side of the substrate;

FIG. 9 is a cross sectional view showing a bank formed on the upper face side of the substrate;

FIG. 10 is a cross sectional view showing a light emitting protecting layer formed in the bank and opening;

FIG. 11 is a cross sectional view showing a positive hole injecting layer formed in the bank and opening;

FIG. 12 is a cross sectional view showing the positive hole injecting layer, interlayer and light emitting layer formed in the opening;

FIG. 13A is an explanatory diagram showing a light emitting image of the EL panel and is an example for comparison of showing an EL panel not including a light emitting protecting layer;

FIG. 13B is an explanatory diagram showing a light emitting image of the EL panel and is an embodiment showing the EL panel where a light emitting protecting layer is formed;

FIG. 14 is a planar view showing another example of an arrangement structure of the pixel of the EL panel;

FIG. 15 is a cross sectional view showing a plane viewed along arrows V-V shown in FIG. 4 of another embodiment;

FIG. 16 is a cross sectional view showing a plane viewed along arrows VI-VI shown in FIG. 4 of another embodiment;

FIG. 17 is a cross sectional view showing the positive hole injecting layer formed in the bank and opening; and

FIG. 18 is a cross sectional view showing the positive hole injecting layer, interlayer and light emitting layer formed in the opening.

### DETAILED DESCRIPTION OF THE PREFERRED EMBODIMENTS

### First Embodiment

A preferred embodiment for carrying out the present invention will be described below with reference to the attached drawings. The embodiments described below include various technically preferable limitations for carrying out the present invention, however, the scope of the invention is not limited to the embodiments described below and the illustrated examples.

Incidentally, in the present embodiment, a light emitting apparatus is applied to the EL panel which is a display apparatus and the present invention will be described.

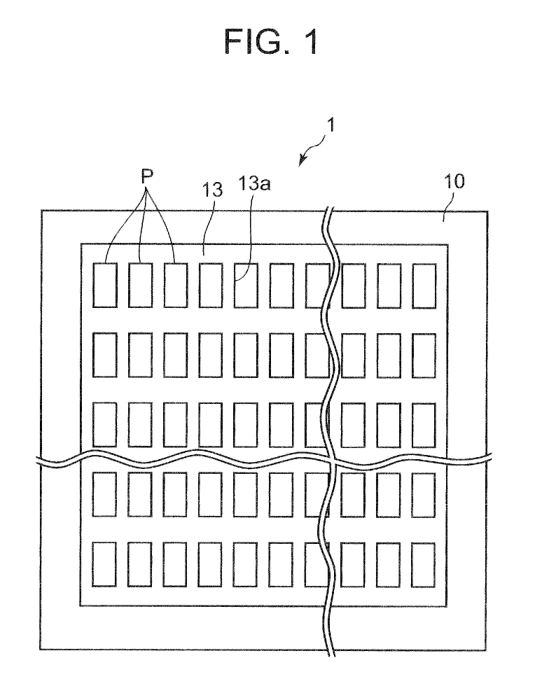

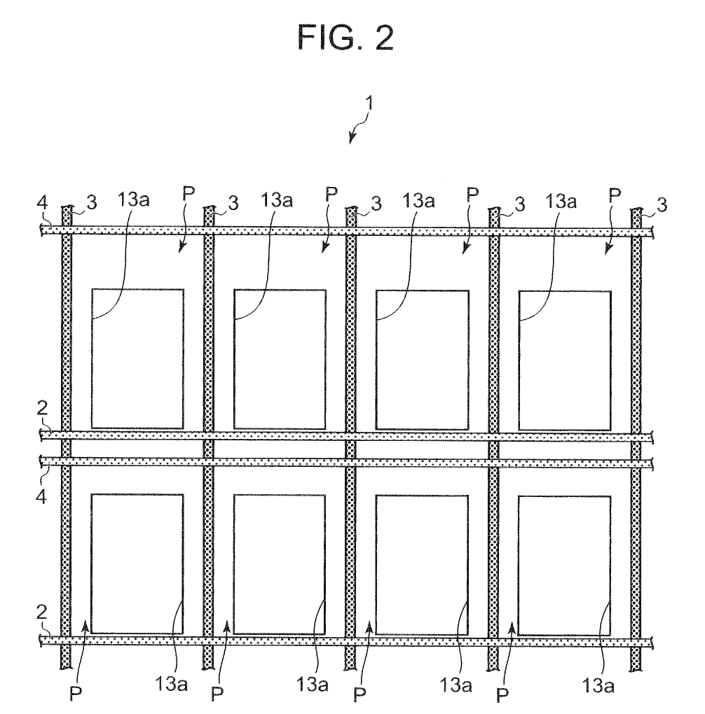

FIG. 1 is a planar view showing an arrangement structure of a plurality of pixels P of the EL panel 1 and FIG. 2 is a planar view showing a schematic structure of the EL panel 1.

As shown in FIG. 1 and FIG. 2, a plurality of pixels P which each emit light of, for example, red (R), green (G) and blue (B) are arranged in a matrix shape in a predetermined pattern on the EL panel 1.

On the EL panel 1, a plurality of scanning lines 2 are arranged along a horizontal direction so as to be substantially parallel to each others and a plurality of signal lines 3 are arranged along a vertical direction substantially orthogonal to the scanning lines 2 from a planar view so as to be substantially parallel to each other. Also, voltage supplying lines 4 are provided between adjacent scanning lines 2 along the scanning lines 2. An area surrounded by each scanning line 2, two adjacent signal lines 3 and each voltage supplying line 4 corresponds to a pixel P.

Also, a bank 13 which is a grid shaped partition wall is provided on the EL panel 1 so as to cover above the scanning lines 2, signal lines 3 and voltage supplying lines 4. A plurality of substantially rectangular shaped openings 13a surrounded by the bank 13 are formed with respect to each pixel P. Later described pixel electrode 8a, light emitting protecting layer 8f, positive hole injecting layer 8b, interlayer 8c, light emitting layer 8d and counter electrode 8e are provided laminated in the opening 13a.

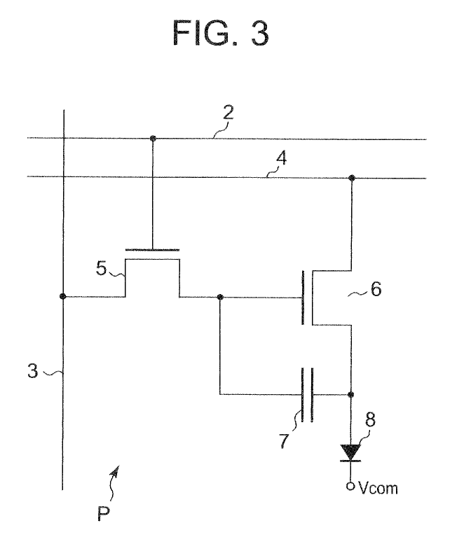

FIG. 3 is a circuit diagram showing a circuit corresponding to one pixel of the EL panel 1 operating with an active matrix driving method.

As shown in FIG. 3, the scanning line 2, the signal line 3 crossing the scanning line 2 and the voltage supplying line 4 along the scanning line 2 are provided on the EL panel 1. Also, a switch transistor 5 which is a thin film transistor, driving transistor 6 which is a thin film transistor, capacitor 7 and EL element 8 are provided with respect to each pixel P of the EL panel 1.

In each pixel P, a gate of the switch transistor 5 is connected to the scanning line 2, either one of a drain or source of the switch transistor 5 is connected to the signal line 3, the other of the drain or source of the switch transistor 5 is connected to one electrode of the capacitor 7 and gate of the driving transistor 6. Either one of a source or drain of the driving transistor 6 is connected to the voltage supplying line 4 and the other of the source or drain of the driving transistor 6 is connected to the other electrode of the capacitor 7 and an anode of the EL element 8. Incidentally, cathode of the EL element 8 of all of the pixels P is maintained at a constant voltage V com (for example, grounded). The switch transistor 5 and the driving transistor 6 can both be n-channel type, both be p-channel type, or one can be n-channel type and the other can be p-channel type.

Also, around the EL panel 1, each scanning line 2 is connected to a scanning driver, each voltage supplying line 4 is connected to a constant voltage source or a driver which outputs a suitable voltage signal, and each signal line 3 is connected to a data driver, and the EL panel 1 is driven with an active matrix driving method by these drivers. A constant voltage source or driver supplies predetermined electric power to the voltage supplying line 4.

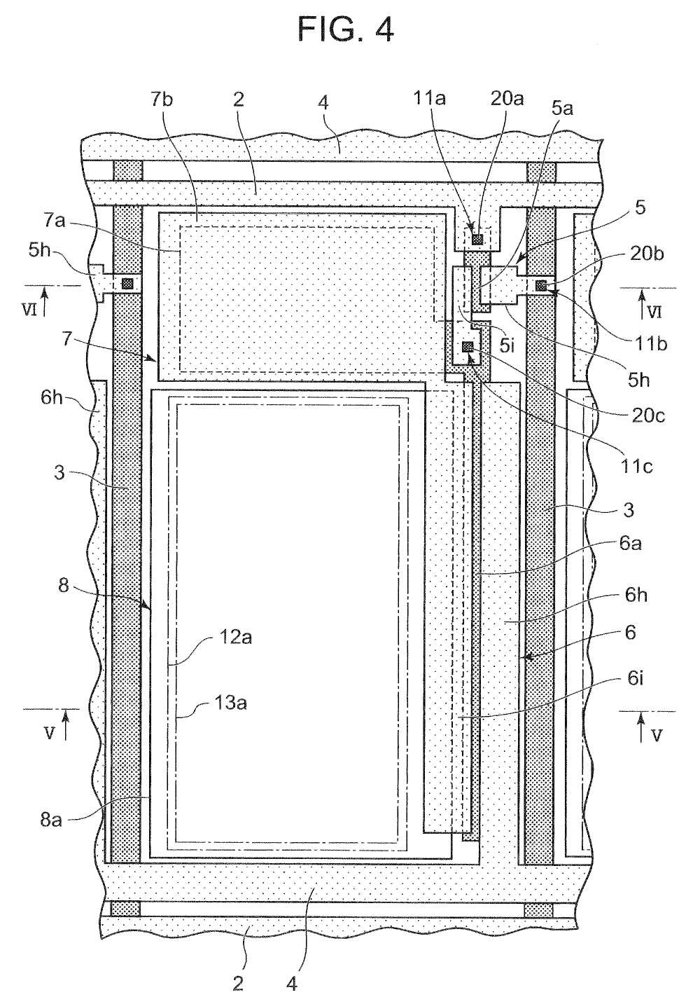

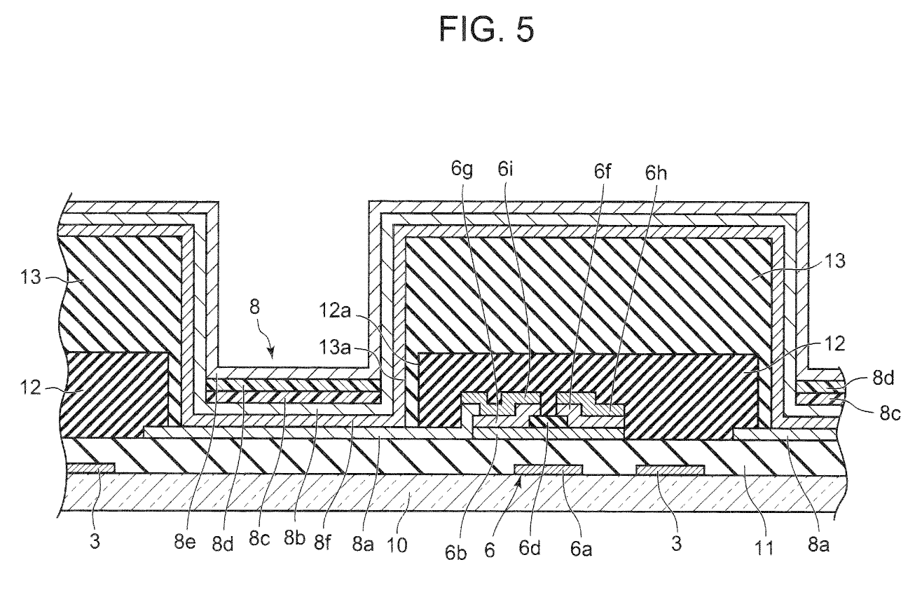

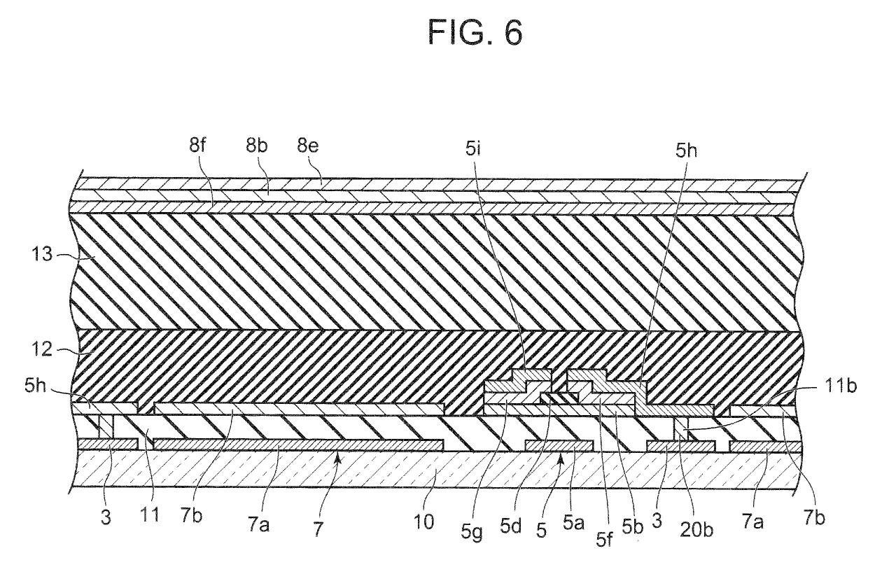

Next, the EL panel 1 and a circuit structure of the pixel P of the EL panel 1 will be described with reference to FIG. 4 to FIG. 6. Here, FIG. 4 is a planar view corresponding to one pixel P of the EL panel 1, FIG. 5 is a cross sectional view showing a plane viewed along arrows V-V shown in FIG. 4, and FIG. 6 is a cross sectional view showing a plane viewed along arrows VI-VI shown in FIG. 4. Incidentally, FIG. 4 mainly shows an electrode and wiring.

As shown in FIG. 4, the switch transistor 5 and driving transistor 6 are arranged along the signal line 3, the capacitor 7 is placed near the switch transistor 5 and the EL element 8 is placed near the driving transistor 6. Also, between the scanning line 2 and voltage supplying line 4 corresponding to the pixel, the switch transistor 5, driving transistor 6, capacitor 7 and EL element 8 are placed.

As shown in FIG. 4 to FIG. 6, a gate insulating film 11 is formed on one face of the substrate 10, and an interlayer insulating film 12 is formed on the switch transistor 5, driving transistor 6 and gate insulating film 11 surrounding the switch transistor 5 and driving transistor 6. The signal line 3 is formed between the gate insulating film 11 and substrate 10, and the scanning line 2 and voltage supplying line 4 are formed between the gate insulating film 11 and interlayer insulating film 12.

Also, as shown in FIG. 4 and FIG. 6, the switch transistor 5 is a thin film transistor with an inversely staggered structure. The switch transistor 5 includes gate electrode 5a, gate insulating film 11, semiconducting film 5b, channel protecting film 5d, impurity semiconducting films 5f, 5g, drain electrode 5h, source electrode 5i, etc.

The gate electrode 5a is formed between the substrate 10 and the gate insulating film 11. The gate electrode 5a includes, for example, Cr film, Al film, Cr/Al laminated film, AlTi alloy film, AlTiNd alloy film, or MoNb alloy film. Also, a gate insulating film 11 with insulating properties is formed on the gate electrode 5a and the gate insulating film 11 covers the gate electrode 5a.

The gate insulating film 11 includes, for example, silicon nitride or silicon oxide. An intrinsic semiconducting film 5b is formed in a position corresponding to the gate electrode 5a on the gate insulating film 11 and the semiconducting film 5b faces the gate electrode 5a with the gate insulating film 11 sandwiched in between.

The semiconducting film 5b includes, for example, amorphous silicon or poly crystalline silicon and a channel is formed on the semiconducting film 5b. Also, a channel protecting film 5d with insulating properties is formed on a center section of the semiconducting film 5b. The channel protecting film 5d includes, for example, silicon nitride or silicon oxide.

Also, an impurity semiconducting film 5f is formed so as to overlap a portion of the channel protecting film 5d on one edge of the semiconducting film 5b and an impurity semiconducting film 5g is formed so as to overlap a portion of the channel protecting film 5d on the other edge of the semiconducting film 5b. The impurity semiconducting films 5f, 5g are each formed on either edge of the semiconducting film 5b, separated from each other. Incidentally, the impurity semiconducting films 5f, 5g are n-type semiconductors, however, the type is not limited to this and can be a p-type semiconductor

The drain electrode 5h is formed on the impurity semiconducting film 5f. The source electrode 5i is formed on the impurity semiconducting film 5g. The drain electrode 5h and source electrode 5i include, for example, Cr film, Al film, Cr/Al laminated film, AlTi alloy film, AlTiNd alloy film or MoNb alloy film.

An interlayer insulating film 12 with insulating properties which is to be a protecting film is formed on the channel protecting film 5d, drain electrode 5h and source electrode 5i, and the interlayer insulating film 12 covers the channel protecting film 5d, drain electrode 5h and source electrode 5i. The interlayer insulating film 12 covers the switch transistor 5. The interlayer insulating film 12 includes, for example, silicon nitride or silicon oxide with a thickness of 100 nm to 200 nm.

Also, as shown in FIG. 4 and FIG. 5, the driving transistor 6 is a thin film transistor with an inversely staggered structure. The driving transistor 6 includes, a gate electrode 6a, gate insulating film 11, semiconducting film 6b, channel protecting film 6d, impurity semiconducting film 6f, 6g, drain electrode 6h, source electrode 6i, etc.

The gate electrode 6a includes, for example, Cr film, Al film, Cr/Al laminated film, AlTi alloy film, AlTiNd alloy film or MoNb alloy film, and the gate electrode 6a is formed between the substrate 10 and the gate insulating film 11 similar to the gate electrode 5a. The gate electrode 6a is covered by a gate insulating film 11 which includes, for example, silicon nitride or silicon oxide.

The semiconducting film 6b formed with a channel is formed in a position corresponding to the gate electrode 6a on the gate insulating film 11 and the semiconducting film 6b is formed including, for example, amorphous silicon or polycrystalline silicon. The semiconducting film 6b faces the gate electrode 6a with the gate insulating film 11 sandwiched in between.

A channel protecting film 6d with insulating properties is formed on a center section of the semiconducting film 6b. The channel protecting film 6d includes, for example, silicon nitride or silicon oxide.

Also, an impurity semiconducting film 6f is formed so as to overlap a portion of the channel protecting film 6d on one edge of the semiconducting film 6b and an impurity semiconducting film 6g is formed so as to overlap a portion of the channel protecting film 6d on the other edge of the semiconducting film 6b. The impurity semiconducting films 6f, 6g are each formed on either edge of the semiconducting film 6b and are separated from each other. Incidentally, the impurity semiconducting films 6f, 6g are an n-type semiconductor, however, the type is not limited to this and can be a p-type semiconductor.

The drain electrode 6h is formed on the impurity semiconducting film 6f. The source electrode 6i is formed on the impurity semiconducting film 6g. The drain electrode 6h and source electrode 6i include, for example, Cr film, Al film, Cr/Al laminated film, AlTi alloy film, AlTiNd alloy film or MoNb alloy film.

An interlayer insulating film 12 with insulating properties which is to be a protecting film is formed on the channel protecting film 6d, drain electrode 6h and source electrode 6i, and the interlayer insulating film 12 covers the channel protecting film 6d, drain electrode 6h and source electrode 6i. The interlayer insulating film 12 covers the driving transistor 6.

As shown in FIG. 4 and FIG. 6, the capacitor 7 includes a pair of electrodes 7a, 7b facing each other and the gate insulating film 11 in between the electrodes as a derivative. One of the electrodes 7a is formed between the substrate 10 and the gate insulating film 11 and the other electrode 7b is formed between the gate insulating film 11 and the interlayer insulating film 12.

Incidentally, the electrode 7a of the capacitor 7 is connected integrally to the gate electrode 6a of the driving transistor 6 and the electrode 7b of the capacitor 7 is connected integrally to the source electrode 6i of the driving transistor 6. Also, the drain electrode 6h of the driving transistor 6 is connected integrally to the voltage supplying line 4.

Incidentally, the signal line 3, electrode 7a of the capacitor 7, gate electrode 5a of the switch transistor 5 and the gate electrode 6a of the driving transistor 6 are collectively formed by shaping the gate metal layer which is a conductive film formed on one face of the substrate 10 using a photolithographic method, etching method, etc.

Also, the scanning line 2, voltage supplying line 4, electrode 7b of the capacitor 7, drain electrode 5h and source electrode 5i of the switch transistor 5, and drain electrode 6h and source electrode 6i of the driving transistor 6 are formed by shaping the source/drain metal layer which is a conductive film formed on one face of the gate insulating film 11, etc. using a photolithographic method, etching method, etc.

Also, on the gate insulating film 11, a contact hole 11a is formed on an area where the gate electrode 5a and the scanning line 2 overlap, a contact hole 11b is formed on an area where the drain electrode 5h and the signal line 3 overlap, a conductive contact hole 11c is formed on an area where the gate electrode 6a and the source electrode 5i overlap and contact plugs 20a to 20c are each implanted in contact holes 11a to 11c. The gate 5a of the switch transistor 5 and the scanning line 2 are electrically continuous by the contact plug 20a, the drain electrode 5h of the switch transistor 5 and the signal line 3 are electrically continuous by the contact plug 20b, and the source electrode 5i of the switch transistor 5 and the electrode 7a of the capacitor 7 as well as the source electrode 5i of the switch transistor 5 and the gate electrode 6a of the driving transistor 6 are electrically continuous by the contact plug 20c. The scanning line 2 can directly contact the gate electrode 5a, the drain electrode 5h can contact the signal line 3 and the source electrode 5i can contact the gate electrode 6a without the contact plugs 20a to 20c.

The pixel electrode 8a is provided on the substrate 10 mediated by the gate insulating film 11, and the pixel electrodes 8a are formed independently with respect to each pixel P. When the EL panel 1 is a bottom emission type where light of the EL element 8 is emitted from the substrate 10, the pixel electrode 8a is a transparent electrode and includes at least any one of, for example, tin doped indium oxide (ITO), zinc doped indium oxide, indium oxide (In₂O₃), tin oxide (SnO₂), zinc oxide (ZnO) or cadmium tin oxide (CTO). When the EL panel 1 is a top emission type where light of the EL element 8 is emitted through the later described counter electrode 8e, the pixel electrode 8a can be a laminated structure of a layer which is to be the above described transparent electrode and light reflecting layer such as Al film, Al alloy film, etc. under the layer of the transparent electrode At this time, the light reflecting layer can be formed by a source/drain metal layer. Incidentally, a portion of the pixel electrode 8a overlaps with the source electrode 6i of the driving transistor 6 and the pixel electrode 8a and the source electrode 6i are connected.

As shown in FIG. 4 to FIG. 6, the interlayer insulating film 12 is formed so as to cover the scanning line 2, signal line 3, voltage supplying line 4, switch transistor 5, driving transistor 6, surrounding edge section of the pixel electrode 8a, the electrode 7b of the capacitor 7 and the gate insulating film 11.

An opening 12a is formed on the interlayer insulating film 12 so that a center section of each pixel electrode 8a is exposed. Therefore, the interlayer insulating film 12 is formed in a grid like shape from a planar view.

As shown in FIG. 4 and FIG. 5, the EL element 8 includes the pixel electrode 8a as a first electrode to be an anode, light emitting protecting layer 8f formed on the pixel electrode 8a and throughout the surface of the later described bank 13, positive hole injecting layer 8b as a carrier transporting layer formed on the light emitting protecting layer 8f, interlayer 8c to function as a portion of the carrier transporting layer formed on the positive hole injecting layer 8b, light emitting layer 8d formed on the interlayer 8c, and counter electrode 8e as a second electrode formed on the light emitting layer 8d. The counter electrode 8e is a cathode common to all of the pixels P and is formed as a single electrode continuing through all of the pixels P.

The light emitting protecting layer 8f is a layer including, for example, poly(ethylenedioxythiophene) (PEDOT) which is a conducting polymer and polystyrene sulfonate (PSS) which is a dopant.

The light emitting protecting layer 8f including the PEDOT/PSS is formed continuing through all of the pixels P (pixel electrode 8a) and covers the pixel electrode 8a and the whole face of the bank 13.

Especially, the light emitting protecting layer 8f is a layer mediating between the positive hole injecting layer 8b and the pixel electrode 8a and between the positive hole injecting layer 8b and the bank 13 so that the positive hole injecting layer 8b is not formed directly on the pixel electrode 8a and the bank 13.

Since the light emitting protecting layer 8f is a low resistance conducting polymer, when forward bias voltage is applied in the thickness direction, the light emitting protecting layer 8f has a function of transporting a positive hole from the pixel electrode 8a to the positive hole injecting layer 8b and also has a function of shielding so that a component of the bank 13 does not move to the positive hole injecting layer 8b.

The positive hole injecting layer 8b is a layer including, for example, transition metal oxide and is a carrier injecting layer to inject the positive hole from the pixel electrode 8a to the light emitting layer 8d. As the positive hole injecting layer 8b, transition metal oxide such as molybdenum oxide, vanadium oxide, tungsten oxide, titanium oxide, etc. can be used, and especially, it is preferable that molybdenum oxide is used.

The positive hole injecting layer 8b is formed on the whole area of the upper face of the light emitting protecting layer 8f corresponding to the whole face of the bank 13 and the opening 13a of the bank 13.

The interlayer 8c is an electron transport suppressing layer including, for example, material of polyfluorene series and has a function of suppressing an electron from moving from the light emitting layer 8d to the positive hole injecting layer 8b side.

The light emitting layer 8d includes organic material which emits light of any one of red (R), green (G), blue (B) with respect to each pixel P, and includes conjugated double bonded polymer such as, light emitting material of polyfluorene series, light emitting material of polyphenylene vinylene series, etc. and is a layer which emits light with the recombination between the electron provided from the counter electrode 8e and the positive hole injected from the positive hole injecting layer 8b. Therefore, the pixel P emitting light of red (R), the pixel P emitting light of green (G), and the pixel P emitting light of blue (B) each include different light emitting material in the light emitting layer 8d. The pattern of red (P), green (G), and blue (B) of pixel P can be in a delta arrangement or stripe pattern where pixels of the same color are arranged in the vertical direction.

When the EL panel 1 is a bottom emission type, the counter electrode 8e can be a laminated structure of a low work function layer where the work function of, for example, Mg, Ca, Ba, Li, etc. is 4.0 eV or less, preferably, 3.0 eV or less and thickness of 30 nm or less and a light reflecting layer such as Al film, Al alloy film, etc. with a thickness of 100 nm or more provided on the low work function layer to reduce sheet resistance.

Also, when the EL panel 1 is a top emission type, the counter electrode 8e can be a laminated structure of the low work function layer as described above and a transparent conducting layer including, for example, tin doped indium oxide (ITO), zinc doped indium oxide, indium oxide (In₂O₃), tin oxide (SnO₂), zinc oxide (ZnO) or cadmium tin oxide (CTO), etc. provided on the low work function layer.

The counter electrode 8e is an electrode common to all of the pixels P and covers the bank 13 with the light emitting layer 8d.

The bank 13 is a partition wall formed on the interlayer insulating film 12 and includes resin material with insulating properties such as resin material of polyimide series with photosensitive properties, etc. When the interlayer 8c and light emitting layer 8d are formed by a wet way, the bank 13 functions as a partition wall so that a liquid body where material which is to be the interlayer 8c and light emitting layer 8d is dissolved or dispersed in a solvent does not flow out to the adjacent pixel P.

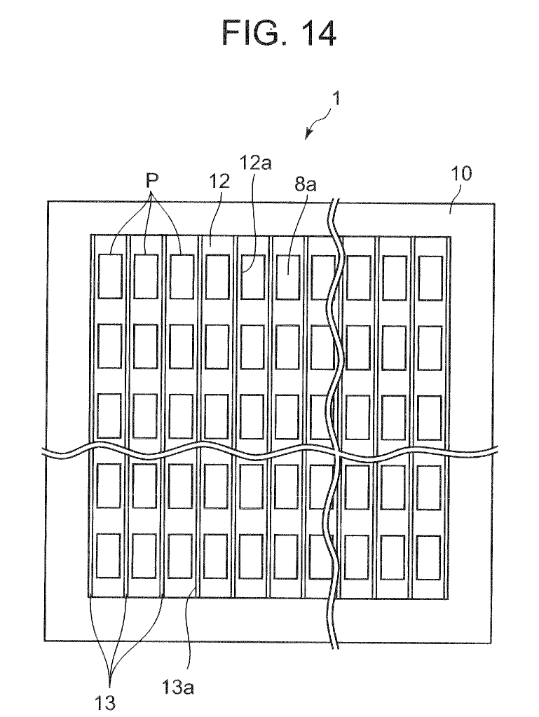

The light emitting layer 8d which is to be the light emitting portion is separated by the bank 13 and the interlayer insulating film 12 with respect to each pixel P. When the pattern of red (R), green (G) and blue (B) of the pixel P is a stripe pattern, as shown in FIG. 14, the bank 13 is arranged in a stripe pattern in the vertical direction along the pixels with the same color, and similar to FIG. 4, the opening 12a is provided on the interlayer insulating film 12 so as to expose the pixel electrode 8a by surrounding the pixel electrode 8a.

In the opening 13a of the bank 13, the light emitting protecting layer 8f, positive hole injecting layer 8b, interlayer 8c, light emitting layer 8d, are sequentially laminated on the pixel electrode 8a.

For example, as shown in FIG. 5, the light emitting protecting layer 8f is laminated on the pixel electrode 8a in the opening 13a of the bank 13 and the positive hole injecting layer 8b is laminated on the light emitting protecting layer 8f.

Then, the liquid body including material which is to be the interlayer 8c is applied on the positive hole injecting layer 8b of each opening 13a and each substrate 10 is heated to dry the liquid body to form a compound film which is laminated as the interlayer 8c.

Further, the liquid body including material which is to be the light emitting layer 8d is applied on the interlayer 8c of each opening 13a and each substrate 10 is heated to dry the liquid body to form a compound film which is laminated as the light emitting layer 8d.

Incidentally, the counter electrode 8e is provided so as to cover the light emitting layer 8d and the bank 13 (see FIG. 5). The EL element 8 can be a structure where the light emitting layer 8d is laminated directly on the positive hole injecting layer 8b without providing an interlayer 8c, or an electron injecting layer can be provided other than the light emitting layer 8d.

The EL panel 1 is driven and emits light in the following way.

In a state where a predetermined level of voltage is applied to all of the voltage supplying lines 4, by sequentially applying an on voltage to the scanning lines 2 with the scanning driver, the switch transistors 5 connected to these scanning lines 2 are sequentially selected.

When each scanning line 2 is selected, by applying a voltage on all of the signal lines 3 with the data driver at a level according to a tone, since the switch transistors 5 corresponding to the selected scanning lines 2 are on, the voltage in the level according to the tone is applied to the gate electrode 6a of the driving transistor 6.

The difference in potential between the gate electrode 6a and source electrode 6i of the driving transistor 6 is fixed according to the voltage applied to the gate electrode 6a of the driving transistor 6 so that the size of the drain-source current of the driving transistor 6 is fixed and the EL element 8 emits light in a brightness according to the drain-source current.

Then, when the selection of the scanning line 2 is cancelled, the switch transistor 5 is turned off, and an electrical charge according to the voltage applied to the gate electrode 6a of the driving transistor 6 is stored in the capacitor 7 so that the difference in potential between the gate electrode 6a and the source electrode 6i of the driving transistor 6 is maintained.

Therefore, the driving transistor 6 continues to pass the drain-source current with the same current value as the time of selection and the light emitting brightness of the EL element 8 is maintained.

Next, the manufacturing method of the EL panel 1 will be described.

A gate metal layer is deposited by sputtering on the substrate 10 and patterned by photolithography to form the signal line 3, electrode 7a of the capacitor 7, gate electrode 5a of the switch transistor 5 and the gate electrode 6a of the driving transistor 6.

Next, the gate insulating film 11 such as silicon nitride is deposited by plasma CVD.

Next, after successively depositing the semiconducting layer such as amorphous silicon which is to be the semiconducting films 5b, 6b and insulating layer such as silicon nitride which is to be the channel protecting films 5d, 6d, a pattern of the channel protecting films 5d, 6d is formed by photolithography and after an impurity layer which is to be the impurity semiconducting films 5f, 5g, 6f, 6g is deposited, the impurity layer and the semiconducting layer are successively patterned by photolithography to form the impurity semiconducting films 5f, 5g, 6f, 6g and semiconducting films 5b, 6b.

Then, a contact hole (not shown) to open the external connecting terminal of each scanning line 2 in order to connect the scanning driver in a position of one edge of the EL panel 1 and contact holes 11a to 11c are formed on the gate insulating film 11 by photolithography. Next, contact plugs 20a to 20c are formed in the contact holes 11a to 11c. The contact plug forming step can be omitted.

Next, when the EL panel 1 is a bottom emission type, the transparent conducting film such as ITO is deposited and then patterned to form the pixel electrode 8a. Here, the pixel electrode 8a is formed so that a region in the vicinity of one side edge overlaps on a region in the vicinity of one side edge of the impurity semiconducting film 6g. Then, the source/drain metal layer which is to be the drain electrode 5h and source electrode 5i of the switch transistor 5 and drain electrode 6h and source electrode 6i of the driving transistor 6 is deposited and suitably patterned to form the scanning line 2, voltage supplying line 4, electrode 7b of the capacitor 7, drain electrode 5h and source electrode 5i of the switch transistor 5 and the drain electrode 6h and source electrode 6i of the driving transistor 6. Here, the region in the vicinity of one side edge of the source electrode 6i overlaps the above described region in the vicinity of one side edge of the pixel electrode 8a and are connected to each other.

When the EL panel 1 is a top emission type, the impurity semiconducting films 5f, 5g, 6f, 6g, semiconducting films 5b, 6b are formed and then the source/drain metal layer is deposited and then patterned to form the scanning line 2, voltage supplying line 4, electrode 7b of the capacitor 7, drain electrode 5h and source electrode 5i of the switch transistor 5 and drain electrode 6h and source electrode 6i of the driving transistor 6 and in addition a light reflecting film can be formed in the area where the pixel electrode 8a is formed The light reflecting film is formed successive to the source electrode 6i. Then, the transparent conducting film such as ITO is deposited and then patterned to form the pixel electrode 8a on the light reflecting film Here, a region in the vicinity of one side edge of the pixel electrode 8a overlaps a region in the vicinity of one side edge of the source electrode 6i and are connected to each other.

Also, when the EL panel 1 is a top emission type, a light reflecting film (silver or Al, etc.) other than source/drain metal layer can be used. In this case, after the impurity semiconducting films 5f, 5g, 6f, 6g and semiconducting films 5b, 6b are formed, the above described other light reflecting film and transparent conducting film such as ITO, etc. are successively deposited and collectively patterned in the shape of the pixel electrode 8a by photolithography. Next, after the source/drain metal layer is deposited, the layer can be patterned to form the scanning line 2, voltage supplying line 4, electrode 7b of the capacitor 7, drain electrode 5h and source electrode 5i of the switch transistor 5, and drain electrode 6h and source electrode 6i of the driving transistor 6. Here, a pixel in the vicinity of one side edge of the source electrode 6i overlaps a region in the vicinity of one side edge of the electrode 8a and are connected to each other. Also, the above described other light reflecting film can be deposited and patterned and then the transparent conducting film such as ITO can be deposited and then patterned. Here, when there is a possibility that the above described other light reflecting film is corroded by the etchant in wet etching of the transparent conducting film, the transparent conducting film can be patterned larger than the above described other light reflecting film so that the transparent conducting film remains not only on an upper face of the above described other light reflecting film but also a side face. Also, when it is not necessary to structure the light reflecting film with the transparent conducting film as part of the pixel electrode 8a, the pixel electrode forming area can be a three layer structure of the above described other light reflecting film, transparent insulating film and transparent conducting film.

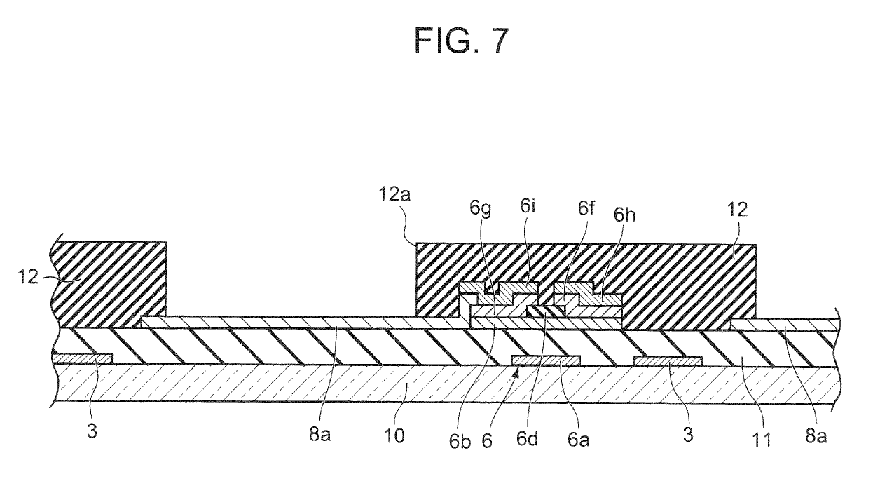

Next, as shown in FIG. 7, the insulating film such as silicon nitride is formed by vapor phase epitaxial method so as to cover the switch transistor 5, driving transistor 6, etc., and by patterning the insulating film by photolithography, the interlayer insulating film 12 including the opening 12a where the center section of the pixel electrode 8a is exposed is formed. With the opening 12a, a plurality of contact holes are formed to open external connecting terminal of the scanning line 2, external connecting terminal of each signal line 3 to connect to the data driver in the position on one edge of the EL panel 1, and external connecting terminal of the voltage supplying line 4, which are not shown.

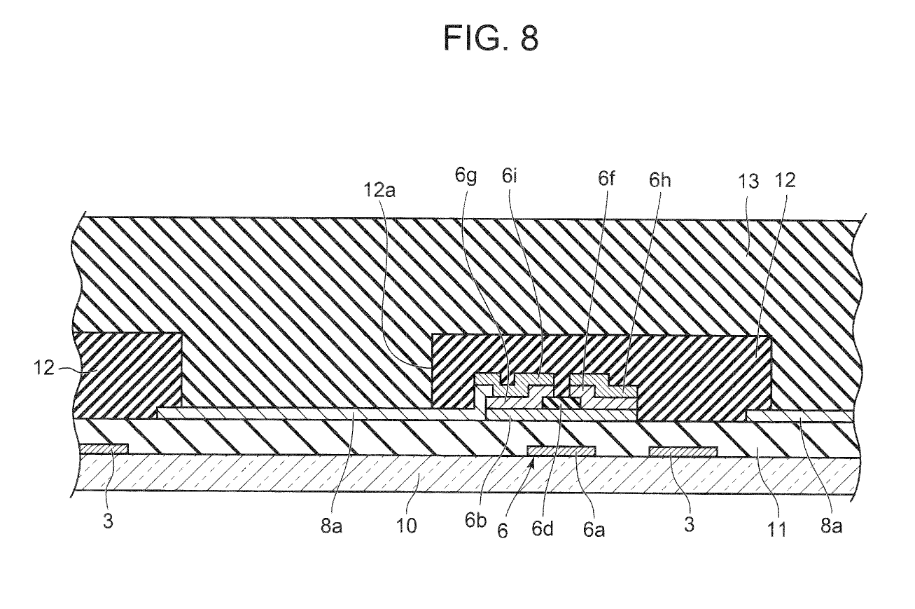

Next, as shown in FIG. 8, a film of photosensitive resin material 13 of polyimide series is formed on the upper face side of the substrate 10 and prebaking is performed.

For example, in the present embodiment, after a film of “Photoneece DW-1000” by Toray Industries, Inc., which is a positive type photosensitive polyimide series resin material, is formed by spin coating, prebaking is performed.

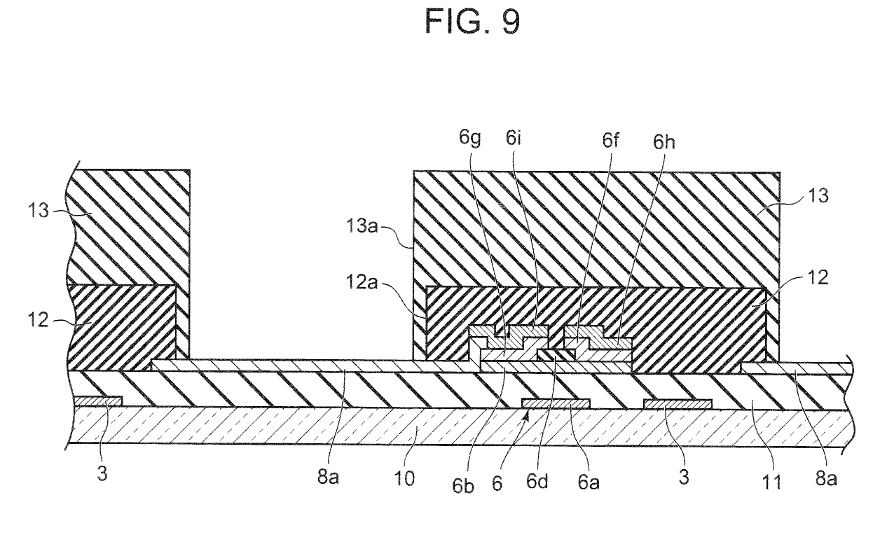

Next, as shown in FIG. 9, after light is exposed on the formed photosensitive resin material 13 using a photomask, developing processing is performed and the grid shaped bank 13 including an opening 13a where the pixel electrode 8a is exposed is formed.

For example, in the present embodiment, after light exposure processing is performed on the formed photosensitive resin material 13 with a predetermined mask pattern, by performing developing processing with tetramethyl ammonium hydroxide (TMAH) aqueous solution, the resin material of the portion corresponding to the opening 13a is eluted to form the opening 13a and the bank 13 is formed. Incidentally, the TMAH aqueous solution as a developing solution is an alkaline aqueous solution.

Then, after washing with water so as to wash away the TMAH aqueous solution attached to the surface of the bank 13 and the surface of the pixel electrode 8a, the substrate 10 with the bank 13 formed is dried and post baking is performed at 180° C. to 250° C. to bake the bank 13.

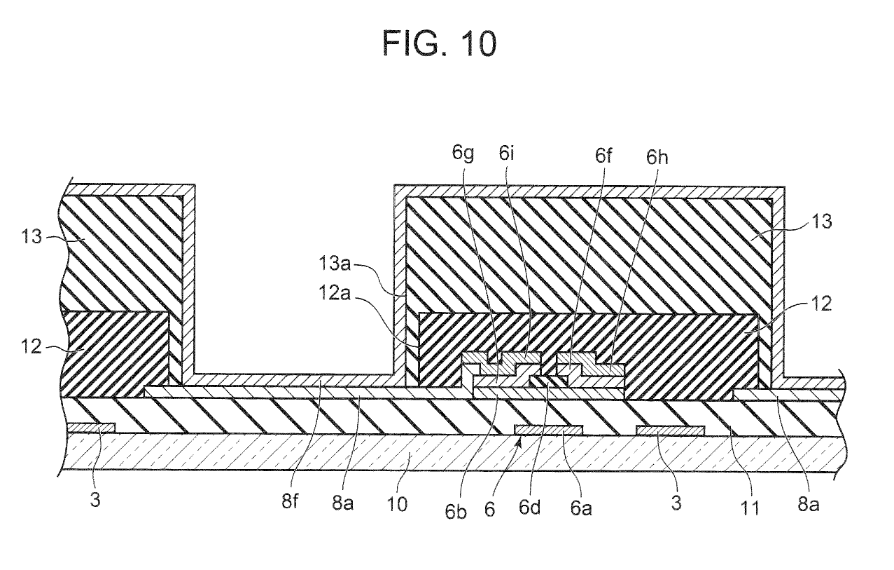

Next, as shown in FIG. 10, the light emitting protecting layer 8f to cover the bank 13 and the pixel electrode 8a exposed in the opening 13a of the bank 13 is formed.

Here, TMAH used in the present embodiment as the developing solution is easily adsorbed and remains on the surface, etc. of the bank 13. Especially, when the positive hole injecting layer 8b such as the molybdenum oxide layer is formed on the bank 13 or pixel electrode 8a in a state where alkaline TMAH remains on the surface of the bank 13 or pixel electrode 8a, the positive hole injecting layer 8b may be altered by the action of the TMAH. In other words, the TMAH which alters the positive hole injecting layer 8b becomes a factor which prevents light emission, and since the positive hole injecting properties of the altered positive hole injecting layer 8b is worsened, there is a possibility that a problem occurs in the light emission of the EL element 8. Therefore, there is a necessity to cover the surface of the bank 13 and pixel electrode 8a with the light emitting protecting layer 8f in order to prevent action of the TMAH remaining on the surface of the bank 13 and pixel electrode 8a to the positive hole injecting layer 8b.

For example, a film of PEDOT of conducting polymer including PSS with strong acidity as a dopant is formed on the surface of the bank 13 and pixel electrode 8a to form the light emitting protecting layer 8f. For example, in the present embodiment, a solution of “CH 8000” of H.C. Starck, Ltd. diluted in pure water to 1/10 is applied by a spin coat method and dried at 180° C. to 200° C. to form the light emitting protecting layer 8f with a thickness of 4 to 5 nm. Lyophilic processing can be performed on the surface of the bank 13 and pixel electrode 8 before forming the light emitting protecting layer 8f.

Specifically, the material solution applied when the light emitting protecting layer 8f is formed is an acidic solution including PSS, and therefore when alkaline TMAH remains on the surface of the bank 13 or pixel electrode 8a, the TMAH can be neutralized or be made acidic and the TMAH as a factor which prevents light emission can be reduced or annihilated.

In other words, by forming the light emitting protecting layer 8f, it is as if the TMAH is sealed with the light emitting protecting layer 8f and it is possible not to directly form the positive hole injecting layer 8b on the bank 13 and the pixel electrode 8a where TMAH may remain. Further, in the step of forming the light emitting protecting layer 8f, neutralizing processing can be performed on the residual TMAH and action of the TMAH to the positive hole injecting layer 8b can be prevented even more.

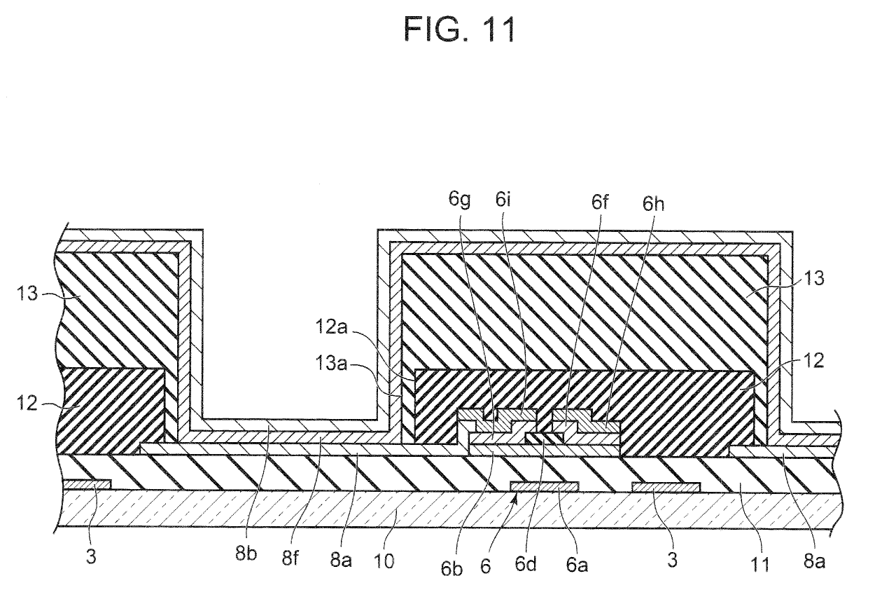

Next, as shown in FIG. 11, using a sputtering method, vacuum evaporation method, etc., a transition metal oxide layer including molybdenum oxide is formed on the light emitting protecting layer 8f on the pixel electrode 8a extending on the light emitting protecting layer 8f on the surface of the bank 13 to form a continuous positive hole injecting layer 8b.

For example, in the present embodiment, a film of molybdenum oxide is formed in a thickness of 30 nm with the evaporation method to form the positive hole injecting layer 8b which covers the light emitting protecting layer 8f corresponding to the whole face of the bank 13 and the opening 13a of the bank 13.

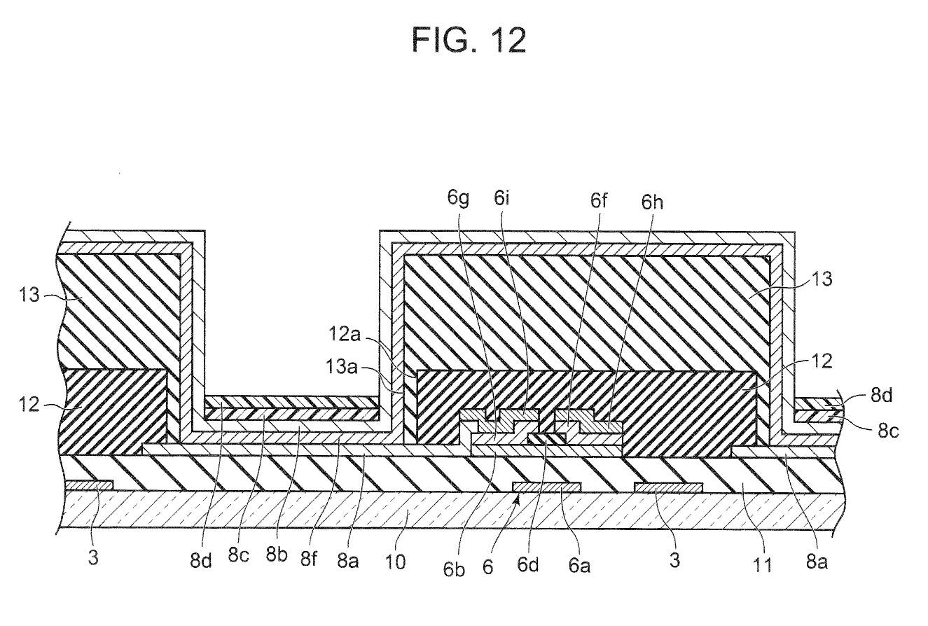

Next, as shown in FIG. 12, a liquid body where organic material to compose the interlayer 8c is dissolved or dispersed in water or an organic solvent such as tetralin, tetramethylbenzene, mesitylene, etc., is applied on the positive hole injecting layer 8b in the opening 13a of the bank 13 with an inkjet method which discharges a plurality of separate droplets or nozzle printing method where a continuous liquid flow flows out and then dried so that the interlayer 8c is laminated and formed on the positive hole injecting layer 8b.

Then, as shown in FIG. 12, a liquid body where organic light emitting material of polyparaphenylene vinylene series or polyfluorene series to compose the light emitting layer 8d is dissolved or dispersed in water or an organic solvent such as tetralin, tetramethylbenzene, mesitylene, etc., is applied on the interlayer 8c in the opening 13a of the bank 13 with an inkjet method or nozzle printing method and then dried to laminate and form the light emitting layer 8d on the interlayer 8c Incidentally, in the present embodiment, for light emitting testing, a solution where green light emitting material of polyfluorene series is dissolved in xylene is applied on the interlayer 8c in the opening 13a to form the light emitting layer 8d. Also, the light emitting layer 8d can be laminated directly on the positive hole injecting layer 8b without providing the interlayer 8c and there can be an electron injecting layer other than the light emitting layer 8d.

Next, as shown in FIG. 5, the counter electrode 8e is formed on one face on the upper face of the positive hole injecting layer 8b on the bank 13 and on the upper face of the light emitting layer 8d in the opening 13a on the bank 13 and the counter electrode 8e which covers the light emitting layer 8d is formed.

For example, in the present embodiment, after forming Ca with an evaporation method at a thickness of 30 nm, Al with low resistance and a stable nature is formed with an evaporation method at a thickness of 500 nm to form the counter electrode 8e.

Then, by forming the counter electrode 8e, the EL element 8 is formed and the EL panel 1 is manufactured.

As described above, before forming the molybdenum oxide layer to form the positive hole injecting layer 8b, by forming a light emitting protecting layer 8f including acidic material on the surface of the bank 13 and pixel electrode 8a exposed to the opening 13a of the bank 13, the alkaline TMAH remaining on the bank 13 and the pixel electrode 8a can be neutralized or be made acidic and be removed. Also the formed light emitting protecting layer 8f is mediated between the positive hole injecting layer 8b and the pixel electrode 8a and between the positive hole injecting layer 8b and the bank 13 and the positive hole injecting layer 8b can be made so as not to be in contact with the bank 13 and the pixel electrode 8a where there is a possibility that the TMAH remains.

As described above, by forming the light emitting protecting layer 8f, action of the TMAH, which is a factor of preventing light emission by altering the positive hole injecting layer 8b, on the positive hole injecting layer 8b can be prevented, and an EL panel 1 including an EL element 8 including a positive hole injecting layer 8b with a good status can be manufactured.

### Example 1

On a glass substrate where a plurality of patterned ITOs are formed, an interlayer insulating film including silicon nitride is formed into a pattern, and after a positive type photosensitive polyimide series resin material (Photoneece DW-1000 by Toray Industries, Inc.) is deposited on the whole face at a thickness of 1 to 5 μm by spin coating, prebaking is performed on the glass substrate deposited with photosensitive polyimide series resin material for two minutes at 120° C. with a hot plate. Then, in the exposure step, the photosensitive polyimide series resin material of the area where the partition wall is not formed is exposed with gh mixed ray at a condition of 50 to 100 mJ/cm² for 5 to 10 seconds, and after the glass substrate is developed with TMAH solution of 2.3% to 2.5%, the glass substrate is cleaned with pure water and spin dried. Next, post baking is performed on the glass substrate for two hours at 180° C. to 320° C. with a clean oven and a bank 13 including an opening 13a is formed. A dilute aqueous solution of PEDOT: PSS acidic solution (CH 8000 by H.C. Starck, Ltd.) diluted to 1/10 is applied to a surface of the bank 13 and on the ITO, and after drying at 180° C. to 200° C., the surface and ITO are covered with a light emitting protecting layer of 4 to 5 nm. On the surface of the light emitting protecting layer, a film of molybdenum oxide is formed at a thickness of 30 nm with an evaporation method. Next, after the interlayer, a light emitting layer of the polyfluorene series (65 nm thickness) are sequentially formed, a film of Ca of 30 nm and Al of 500 nm as a cathode are successively formed by evaporation.

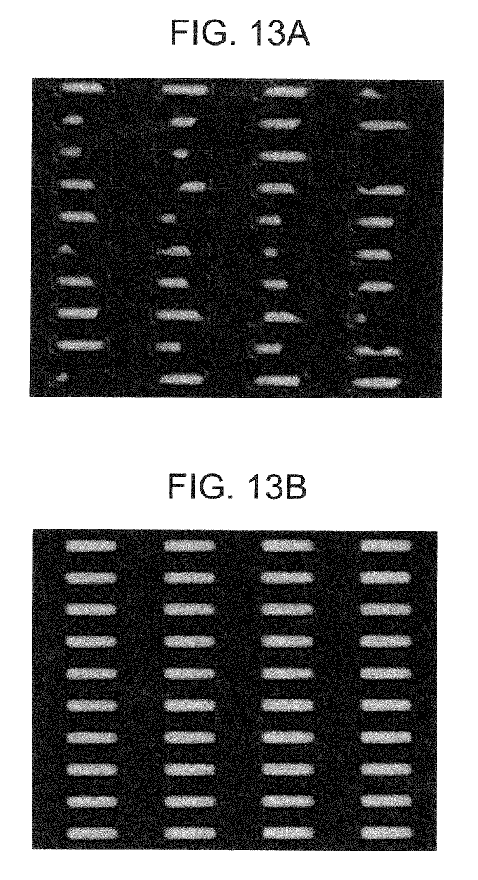

Then, when a light emitting experiment of the EL panel 1 mediating on the bottom layer side of the positive hole injecting layer 8b was performed, as shown in FIG. 13B, it was confirmed that each pixel P of the EL panel 1 composing an EL element 8 suitably emits light.

On the other hand, when a light emitting experiment of the EL panel with a positive hole injecting layer 8b was performed with the same condition as those of the example 1 except without forming the light emitting protecting layer 8f, as shown in FIG. 13A, it was confirmed that there are partial areas where the EL element 8 does not emit light in random places of the EL panel, in other words, dark spots appear. This is because a factor which prevents light emission such as TMAH with an alkaline property alters the positive hole injecting layer 8b including molybdenum oxide, etc. and the positive hole injecting property of the altered positive hole injecting layer 8b is worsened, and an EL element 8 which does not emit light appears.

According to the above results, a manufacturing method of the EL panel where after forming a bank 13 by using TMAH with an alkaline property as a developing solution, the light emitting protecting layer 8f is formed before the positive hole injecting layer 8b is formed in the step of forming the positive hole injecting layer 8b including molybdenum oxide, can be said to be a technique which enables manufacturing of the EL panel (light emitting apparatus) with excellent light emitting properties.

Also, the EL panel 1 formed based on the above manufacturing method where the positive hole injecting layer 8b is formed after forming the light emitting protecting layer 8f, can be said to be a light emitting apparatus with excellent light emitting properties.

### Example 2

On a glass substrate where a plurality of patterned ITOs are formed, an interlayer insulating film including silicon nitride is formed into a pattern, and after a positive type photosensitive polyimide series resin material (Photoneece DW-1000 by Toray Industries, Inc.) is deposited with a thickness of 1 to 5 μm by spin coating, prebaking is performed on the glass substrate deposited with photosensitive polyimide series resin material for two minutes at 120° C. with a hot plate. Then, in the exposure step, the photosensitive polyimide series resin material of the area where the partition wall is not formed is exposed with gh mixed ray at a condition of 50 to 100 mJ/cm² for 5 to 10 seconds, and after the glass substrate is developed with TMAH solution of 2.3% to 2.5%, the glass substrate is cleaned with pure water and spin dried. Next, post baking is performed on the glass substrate for two hours at 180° C. to 320° C. with a clean oven and a bank including an opening is formed. After a film of germanium oxide (GeO₂) with a thickness of 2 nm is formed on the surface of the bank and on the ITO as a light emitting protecting layer with sputtering, similar to the example 1, on the surface of the light emitting protecting layer, a layer of molybdenum oxide is formed at a thickness of 30 nm with an evaporation method and next, after the interlayer, a light emitting layer (65 nm thickness) are sequentially formed, a film of Ba of 3 nm and Al of 500 nm as a cathode are successively formed by evaporation. It was confirmed that the germanium oxide prevented the components of the bank from moving to the molybdenum oxide and dark spots do not occur.

Even with a light emitting protecting layer 8f including germanium oxide (GeO₂), by mediating the layer between the positive hole injecting layer 8b and the pixel electrode 8a, and between the positive hole injecting layer 8b and the bank 13, it is as if the light emitting protecting layer 8f seals the TMAH and it is possible to prevent the positive hole injecting layer 8b from making contact with the bank 13 and the pixel electrode 8a where there is a possibility that TMAH remains.

Since the light emitting protecting layer 8f including GeO₂ includes positive hole injecting properties, when laminated to the positive hole injecting layer 8b, the light emitting protecting layer 8f functions as a part of the positive hole injecting layer and can further prevent action of TMAH, which is a factor of preventing light emission, to the positive hole injecting layer 8b. Consequently, the EL panel 1 including the EL element 8 including a positive hole injecting layer 8b with a good status can be manufactured.

Incidentally, the present embodiment is not limited to the above described embodiments.

For example, the light emitting protecting layer 8f is not limited to a layer formed from PEDOT/PSS and can be a layer of metallic oxide (oxide of an element of IV group) such as silicon oxide (SiO₂) which does not prevent hole injecting properties formed to a few nm. The method of manufacturing the EL panel 1 with the silicon oxide as the light emitting protecting layer 8f is similar to the method of the EL panel 1 with germanium oxide, and thus the description is omitted.

Incidentally, according to the above described embodiment, an example where the light emitting apparatus is applied to an EL panel which is a display apparatus is described, however the present invention is not limited to this, and the present invention can be applied to, for example, a light exposing apparatus, light addressing apparatus and lighting apparatus.

Also, needless to say, other specific details, etc. can be suitably modified.

### Second Embodiment

A preferred embodiment for carrying out the present invention will be described below with reference to the attached drawings The embodiments described below include various technically preferable limitations for carrying out the present invention, however, the scope of the invention is not limited to the embodiments described below and the illustrated examples.

Incidentally, in the present embodiment, a light emitting apparatus is applied to the EL panel which is a display apparatus and the present invention will be described.

FIG. 1 is a planar view showing an arrangement structure of a plurality of pixels P of the EL panel 1 and FIG. 2 is a planar view showing a schematic structure of the EL panel 1.

As shown in FIG. 1 and FIG. 2, a plurality of pixels P which each emit light of, for example, red (R), green (G) and blue (B) are arranged in a matrix shape in a predetermined pattern on the EL panel 1.

On the EL panel 1, a plurality of scanning lines 2 are arranged along a horizontal direction so as to be substantially parallel to each other, and a plurality of signal lines 3 are arranged along a vertical direction substantially orthogonal to the scanning lines 2 from a planar view so as to be substantially parallel to each other. Also, voltage supplying lines 4 are provided between adjacent scanning lines 2 along the scanning lines 2. An area surrounded by each scanning line 2, two adjacent signal lines 3 and each voltage supplying line 4 corresponds to a pixel P.

Also, a bank 13 which is a grid shaped partition wall is provided on the EL panel 1 so as to cover above the scanning lines 2, signal lines 3 and voltage supplying lines 4. A plurality of substantially rectangular shaped openings 13a surrounded by the bank 13 are formed with respect to each pixel P. Later described pixel electrode 8a, positive hole injecting layer 8b, interlayer 8c and light emitting layer 8d are provided in the opening 13a.

FIG. 3 is a circuit diagram showing a circuit corresponding to one pixel of the EL panel 1 operating with an active matrix driving method.

As shown in FIG. 3, the scanning line 2, the signal line 3 crossing the scanning line 2 and the voltage supplying line 4 along the scanning line 2 are provided on the EL panel 1. Also, a switch transistor 5 which is a thin film transistor, driving transistor 6 which is a thin film transistor, capacitor 7 and EL element 8 which is a light emitting element are provided with respect to each pixel P of the EL panel 1.

In each pixel P, a gate of the switch transistor 5 is connected to the scanning line 2, either one of a drain or source of the switch transistor 5 is connected to the signal line 3, the other of the drain or source of the switch transistor 5 is connected to one electrode of the capacitor 7 and gate of the driving transistor 6. Either one of a source or drain of the driving transistor 6 is connected to the voltage supplying line 4 and the other of the source or drain of the driving transistor 6 is connected to the other electrode of the capacitor 7 and an anode of the EL element 8. Incidentally, cathode of the EL element 8 of all of the pixels P is maintained at a constant voltage V com (for example, grounded) The switch transistor 5 and the driving transistor 6 can both be n-channel type, both be p-channel type, or one can be n-channel type and the other can be p-channel type.

Also, around the EL panel 1, each scanning line 2 is connected to a scanning driver, each voltage supplying line 4 is connected to a constant voltage source or a driver which outputs a suitable voltage signal, and each signal line 3 is connected to a data driver, and the EL panel 1 is driven with an active matrix driving method by these drivers. A constant voltage source or driver supplies predetermined electric power to the voltage supplying line 4.

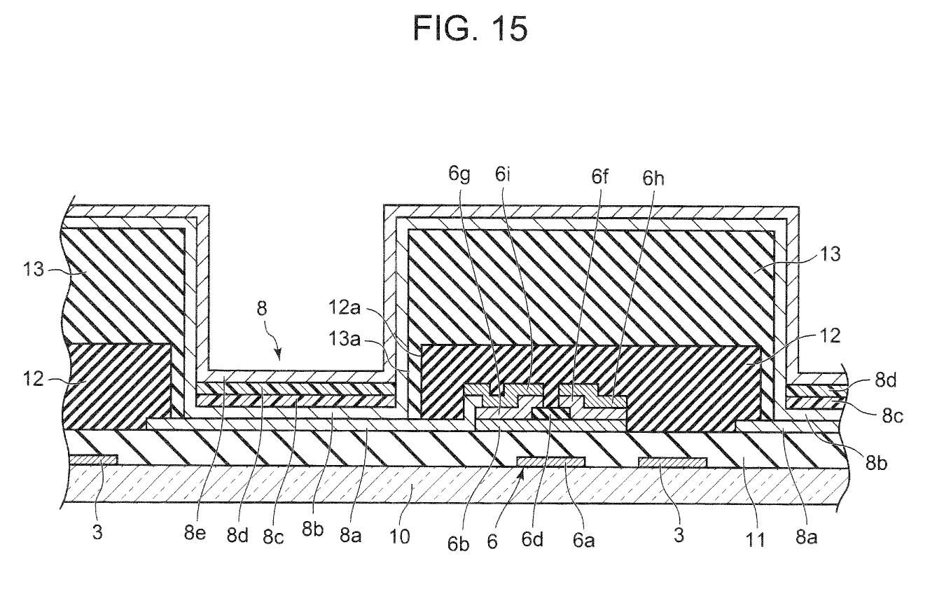

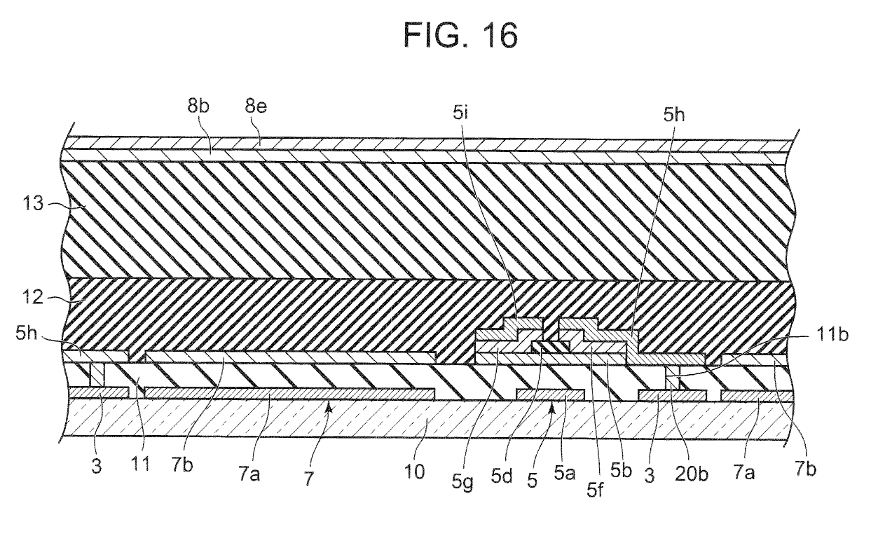

Next, the EL panel 1 and a circuit structure of the pixel P of the EL panel 1 will be described with reference to FIG. 4, FIG. 15 and FIG. 16. Here, FIG. 4 is a planar view corresponding to one pixel P of the EL panel 1, FIG 15 is a cross sectional view showing a plane viewed along arrows V-V shown in FIG. 4, and FIG. 16 is a cross sectional view showing a plane viewed along arrows VI-VI shown in FIG. 4. Incidentally, FIG. 4 mainly shows an electrode and wiring.

As shown in FIG. 4, the switch transistor 5 and driving transistor 6 are arranged along the signal line 3, the capacitor 7 is placed near the switch transistor 5 and the EL element 8 is placed near the driving transistor 6. Also, between the scanning line 2 and voltage supplying line 4 corresponding to the pixel, the switch transistor 5, driving transistor 6, capacitor 7 and EL element 8 are placed.

As shown in FIG. 4, FIG. 15, and FIG. 16, a gate insulating film 11 is formed on one face of the substrate 10, and an interlayer insulating film 12 is formed on the switch transistor 5, driving transistor 6 and gate insulating film 11 surrounding the switch transistor 5 and driving transistor 6. The signal line 3 is formed between the gate insulating film 11 and substrate 10, and the scanning line 2 and voltage supplying line 4 are formed between the gate insulating film 11 and interlayer insulating film 12.

Also, as shown in FIG. 4 and FIG. 16, the switch transistor 5 is a thin film transistor with an inversely staggered structure. The switch transistor 5 includes gate electrode 5a, gate insulating film 11, semiconducting film 5b, channel protecting film 5d, impurity semiconducting films 5f, 5g, drain electrode 5h, source electrode 5i, etc.

The gate electrode 5a is formed between the substrate 10 and the gate insulating film 11. The gate electrode 5a includes, for example, Cr film, Al film, Cr/Al laminated film, AlTi alloy film, AlTiNd alloy film, or MoNb alloy film. Also, a gate insulating film 11 with insulating properties is formed on the gate electrode 5a and the gate insulating film 11 covers the gate electrode 5a.

The gate insulating film 11 includes, for example, silicon nitride or silicon oxide. An intrinsic semiconducting film 5b is formed in a position corresponding to the gate electrode 5a on the gate insulating film 11 and the semiconducting film 5b faces the gate electrode 5a with the gate insulating film 11 sandwiched in between.

The semiconducting film 5b includes, for example, amorphous silicon or poly crystalline silicon and a channel is formed on the semiconducting film 5b. Also, a channel protecting film 5d with insulating properties is formed on a center section of the semiconducting film 5b. The channel protecting film 5d includes, for example, silicon nitride or silicon oxide.

Also, an impurity semiconducting film 5f is formed so as to overlap a portion of the channel protecting film 5d on one edge of the semiconducting film 5b and an impurity semiconducting film 5g is formed so as to overlap a portion of the channel protecting film 5d on the other edge of the semiconducting film 5b. The impurity semiconducting films 5f, 5g are each formed on either edge of the semiconducting film 5b, separated from each other. Incidentally, the impurity semiconducting films 5f, 5g are n-type semiconductors, however, the type is not limited to this and can be a p-type semiconductor.

The drain electrode 5h is formed on the impurity semiconducting film 5f. The source electrode 5i is formed on the impurity semiconducting film 5g. The drain electrode 5h and source electrode 5i include, for example, Cr film, Al film, Cr/Al laminated film, AlTi alloy film, or AlTiNd alloy film.

An interlayer insulating film 12 with insulating properties which is to be a protecting film is formed on the channel protecting film 5d, drain electrode 5h and source electrode 5i, and the interlayer insulating film 12 covers the channel protecting film 5d, drain electrode 5h and source electrode 5i. The interlayer insulating film 12 covers the switch transistor 5. The interlayer insulating film 12 includes, for example, silicon nitride or silicon oxide with a thickness of 100 nm to 200 nm.

Also, as shown in FIG. 4 and FIG. 15, the driving transistor 6 is a thin film transistor with an inversely staggered structure. The driving transistor 6 includes, a gate electrode 6a, gate insulating film 11, semiconducting film 6b, channel protecting film 6d, impurity semiconducting film 6f, 6g, drain electrode 6h, source electrode 6i, etc.

The gate electrode 6a includes, for example, Cr film, Al film, Cr/Al laminated film, AlTi alloy film, AlTiNd alloy film or MoNb alloy film, and the gate electrode 6a is formed between the substrate 10 and the gate insulating film 11 similar to the gate electrode 5a. The gate electrode 6a is covered by a gate insulating film 11 which includes, for example, silicon nitride or silicon oxide.

The semiconducting film 6b formed with a channel is formed in a position corresponding to the gate electrode 6a on the gate insulating film 11 and the semiconducting film 6b is formed including, for example, amorphous silicon or polycrystalline silicon. The semiconducting film 6b faces the gate electrode 6a with the gate insulating film 11 sandwiched in between.

A channel protecting film 6d with insulating properties is formed on a center section of the semiconducting film 6b. The channel protecting film 6d includes, for example, silicon nitride or silicon oxide.

Also, an impurity semiconducting film 6f is formed so as to overlap a portion of the channel protecting film 6d on one edge of the semiconducting film 6b and an impurity semiconducting film 6g is formed so as to overlap a portion of the channel protecting film 6d on the other edge of the semiconducting film 6b. The impurity semiconducting films 6f, 6g are each formed on either edge of the semiconducting film 6b and are separated from each other. Incidentally, the impurity semiconducting films 6f, 6g are an n-type semiconductor, however, the type is not limited to this and can be a p-type semiconductor.

The drain electrode 6h is formed on the impurity semiconducting film 6f The source electrode 6i is formed on the impurity semiconducting film 6g. The drain electrode 6h and source electrode 6i include, for example, Cr film, Al film, Cr/Al laminated film, AlTi alloy film, AlTiNd alloy film or MoNb alloy film.

An interlayer insulating film 12 with insulating properties which is to be a protecting film is formed on the channel protecting film 6d, drain electrode 6h and source electrode 6i, and the interlayer insulating film 12 covers the channel protecting film 6d, drain electrode 6h and source electrode 6i. The interlayer insulating film 12 covers the driving transistor 6.

As shown in FIG. 4 and FIG. 16, the capacitor 7 includes a pair of electrodes 7a, 7b facing each other and the gate insulating film 11 in between the electrodes as a derivative. One of the electrodes 7a is formed between the substrate 10 and the gate insulating film 11 and the other electrode 7b is formed between the gate insulating film 11 and the interlayer insulating film 12.

Incidentally, the electrode 7a of the capacitor 7 is connected integrally to the gate electrode 6a of the driving transistor 6 and the electrode 7b of the capacitor 7 is connected integrally to the source electrode 6i of the driving transistor 6. Also, the drain electrode 6h of the driving transistor 6 is connected integrally to the voltage supplying line 4.

Incidentally, the signal line 3, electrode 7a of the capacitor 7, gate electrode 5a of the switch transistor 5 and the gate electrode 6a of the driving transistor 6 are collectively formed by shaping the gate metal layer which is a conductive film formed on one face of the substrate 10 using a photolithographic method, etching method, etc.

Also, the scanning line 2, voltage supplying line 4, electrode 7b of the capacitor 7, drain electrode 5h and source electrode 5i of the switch transistor 5, and drain electrode 6h and source electrode 6i of the driving transistor 6 are formed by shaping the source/drain metal layer which is a conductive film formed on one face of the gate insulating film 11, etc. using a photolithographic method, etching method, etc.

Also, on the gate insulating film 11, a contact hole 11a is formed on an area where the gate electrode 5a and the scanning line 2 overlap, a contact hole 11b is formed on an area where the drain electrode 5h and the signal line 3 overlap, a contact hole 11c is formed on an area where the gate electrode 6a and the source electrode 5i overlap and conductive contact plugs 20a to 20c are each implanted in contact holes 11a to 11c. The gate 5a of the switch transistor 5 and the scanning line 2 are electrically continuous by the contact plug 20a, the drain electrode 5h of the switch transistor 5 and the signal line 3 are electrically continuous by the contact plug 20b, and the source electrode 5i of the switch transistor 5 and the electrode 7a of the capacitor 7 as well as the source electrode 5i of the switch transistor 5 and the gate electrode 6a of the driving transistor 6 are electrically continuous by the contact plug 20c. The scanning line 2 can directly contact gate electrode 5a, the drain electrode 5h can contact signal line 3 and the source electrode 5i can contact gate electrode 6a without the contact plugs 20a to 20c.

The pixel electrode 8a is provided on the substrate 10 mediated by the gate insulating film 11, and the pixel electrodes 8a are formed independently with respect to each pixel P. When the EL panel 1 is a bottom emission type where light of the EL element 8 is emitted from the substrate 10, the pixel electrode 8a is a transparent electrode and includes at least any one of, for example, tin doped indium oxide (ITO), zinc doped indium oxide, indium oxide (In₂O₃), tin oxide (SnO₂), zinc oxide (ZnO) or cadmium tin oxide (CTO). When the EL panel 1 is a top emission type where light of the EL element 8 is emitted through the later described counter electrode 8e, the pixel electrode 8a can be a laminated structure of a layer which is to be the above described transparent electrode and light reflecting layer such as Al film, Al alloy film Cr film, etc. directly under the layer of the transparent electrode or mediated by a transparent insulating film. At this time, the light reflecting layer can be formed by a source/drain metal layer. Incidentally, a portion of the pixel electrode 8a overlaps with the source electrode 6i of the driving transistor 6 and the pixel electrode 8a and the source electrode 6i are connected.

As shown in FIG. 4, FIG. 15 and FIG. 16, the interlayer insulating film 12 is formed so as to cover the scanning line 2, signal line 3, voltage supplying line 4, switch transistor 5, driving transistor 6, surrounding edge section of the pixel electrode 8a, the electrode 7b of the capacitor 7 and the gate insulating film 11.

An opening 12a is formed on the interlayer insulating film 12 so that a center section of each pixel electrode 8a is exposed. Therefore, the interlayer insulating film 12 is formed in a grid like shape from a planar view.

As shown in FIG. 4 and FIG. 15, the EL element 8 includes the pixel electrode 8a as a first electrode to be an anode, positive hole injecting layer 8b as a carrier transporting layer formed on the pixel electrode 8a, interlayer 8c to function as a portion of the carrier transporting layer formed on the positive hole injecting layer 8b, light emitting layer 8d as a carrier transporting layer formed on the interlayer 8c, and counter electrode 8e as a second electrode formed on the light emitting layer 8d. The counter electrode 8e is a single electrode (cathode) common to all of the pixels P and is formed to continue through all of the pixels P.

The positive hole injecting layer 8b is a layer including, for example, transition metal oxide and is a carrier injecting layer to inject the positive hole from the pixel electrode 8a to the light emitting layer 8d. As the positive hole injecting layer 8b, transition metal oxide such as molybdenum oxide, vanadium oxide, tungsten oxide, titanium oxide, etc. can be used, and especially, it is preferable that molybdenum oxide is used.

The interlayer 8c is an electron transport suppressing layer including, for example, material of polyfluorene series and has a function of suppressing an electron from moving from the light emitting layer 8d to the positive hole injecting layer 8b side when forward bias is applied.

The light emitting layer 8d includes organic material which emits light of any one of red (R), green (G), blue (B) with respect to each pixel P, and includes conjugated double bonded polymer such as, light emitting material of polyfluorene series, light emitting material of polyphenylene vinylene series, etc. and is a layer which emits light with the recombination between the electron provided from the counter electrode 8e and the positive hole injected from the positive hole injecting layer 8b. Therefore, the pixel P emitting light of red (R), the pixel P emitting light of green (G), and the pixel P emitting light of blue (B) each include different light emitting material in the light emitting layer 8d. The pattern of red (R) green (G) and blue (B) of pixel P can be in a delta arrangement or stripe pattern where pixels of the same color are arranged in the vertical direction.

When the EL panel 1 is a bottom emission type, the counter electrode 8e can be a laminated structure of a low work function layer where the work function of, for example, Mg, Ca, Ba, Li, etc. is 4.0 eV or less, preferably, 3.0 eV or less and thickness of 30 nm or less and a light reflecting layer such as Al film, Al alloy film, etc. with a thickness of 100 nm or more provided on the low work function layer to reduce sheet resistance.

Also, when the EL panel 1 is a top emission type, the counter electrode 8e can be a laminated structure of the low work function layer as described above and a transparent conducting layer including, for example, tin doped indium oxide (ITO), zinc doped indium oxide, indium oxide (In₂O₃), tin oxide (SnO₂) zinc oxide (ZnO) or cadmium tin oxide (CTO), etc. provided on the low work function layer.

The counter electrode 8e is an electrode common to all of the pixels P and covers the later described bank 13 with the light emitting layer 8d.

The bank 13 is a partition wall formed on the interlayer insulating film 12 and includes resin material with insulating properties such as resin material of polyimide series with photosensitive properties, etc. When the interlayer 8c and light emitting layer 8d are formed by a wet way, the bank 13 functions as a partition wall so that a liquid body where material which is to be the interlayer 8c and light emitting layer 8d is dissolved or dispersed in a solvent does not flow out to the adjacent pixel P.

The light emitting layer 8d which is to be the light emitting portion is separated by the bank 13 and the interlayer insulating film 12 with respect to each pixel P. When the pattern of red (R), green (G) and blue (B) of the pixel P is a stripe pattern, as shown in FIG. 14, the bank 13 is arranged in a stripe pattern in the vertical direction along the pixels with the same color, and similar to FIG. 4, the opening 12a is provided on the interlayer insulating film 12 so as to expose the pixel electrode 8a by surrounding the pixel electrode 8a.

In the opening 13a of the bank 13, the positive hole injecting layer 8b, interlayer 8c, light emitting layer 8d, are sequentially laminated on the pixel electrode 8a.

For example, as shown in FIG. 15, the positive hole injecting layer 8b is laminated on the pixel electrode 8a in the opening 13a of the bank 13.

Then, the liquid body including material which is to be the interlayer 8c is applied on the positive hole injecting layer 8b of each opening 13a and each substrate 10 is heated to dry the liquid body to form a compound film which is laminated as the interlayer 8c.

Further, the liquid body including material which is to be the light emitting layer 8d is applied on the interlayer 8c of each opening 13a and each substrate 10 is heated to dry the liquid body to form a compound film which is laminated as the light emitting layer 8d.

Incidentally, the counter electrode 8e is provided so as to cover the light emitting layer 8d and the bank 13 (see FIG. 15).

The EL panel 1 is driven and emits light in the following way.

In a state where a predetermined level of voltage is applied to all of the voltage supplying lines 4, by sequentially applying an on voltage to the scanning lines 2 with the scanning driver, the switch transistors 5 connected to these scanning lines 2 are sequentially selected.

When each scanning line 2 is selected, by applying a voltage on all of the signal lines 3 with the data driver at a level according to a tone, since the switch transistors 5 corresponding to the selected scanning lines 2 are on, the voltage in the level according to the tone is applied to the gate electrode 6a of the driving transistor

The difference in potential between the gate electrode 6a and source electrode 6i of the driving transistor 6 is fixed according to the voltage applied to the gate electrode 6a of the driving transistor 6 so that the size of the drain-source current of the driving transistor 6 is fixed and the EL element 8 emits light in a brightness according to the drain-source current.

Then, when the selection of the scanning line 2 is cancelled, the switch transistor 5 is turned off, and an electrical charge according to the voltage applied to the gate electrode 6a of the driving transistor 6 is stored in the capacitor 7 so that the difference in potential between the gate electrode 6a and the source electrode 6i of the driving transistor 6 is maintained.

Therefore, the driving transistor 6 continues to pass the drain-source current with the same current value as the time of selection and the light emitting brightness of the EL element 8 is maintained.

Next, the manufacturing method of the EL panel 1 will be described.

A gate metal layer is deposited by sputtering on the substrate 10 and patterned by photolithography to form the signal line 3, electrode 7a of the capacitor 7, gate electrode 5a of the switch transistor 5 and the gate electrode 6a of the driving transistor 6.

Next, the gate insulating film 11 such as silicon nitride is deposited by plasma CVD.

Next, after successively depositing the semiconducting layer such as amorphous silicon which is to be the semiconducting films 5b, 6b and insulating layer such as silicon nitride which is to be the channel protecting films 5d, 6d, a pattern of the channel protecting films 5d, 6d is formed by photolithography and after an impurity layer which is to be the impurity semiconducting films 5f, 5g, 6f, 6g is deposited, the impurity layer and the semiconducting layer are successively patterned by photolithography to form the impurity semiconducting films 5f, 5g, 6f, 6g and semiconducting films 5b, 6b.

Then, a contact hole (not shown) to open the external connecting terminal of each scanning line 2 in order to connect the scanning driver in a position of one edge of the EL panel 1 and contact holes 11a to 11c are formed on the gate insulating film 11 by photolithography. Next, contact plugs 20a to 20c are formed in the contact holes 11a to 11c. The contact plug forming step can be omitted.

Next, when the EL panel 1 is a bottom emission type, the transparent conducting film such as ITO is deposited and then patterned to form the pixel electrode 8a. Here, the pixel electrode 8a is formed so that a region in the vicinity of one side edge overlaps on a region in the vicinity of one side edge of the impurity semiconducting film 6g. Then, the source/drain metal layer which is to be the drain electrode 5h and source electrode 5i of the switch transistor 5 and drain electrode 6h and source electrode 6i of the driving transistor 6 is deposited and suitably patterned to form the scanning line 2, voltage supplying line 4, electrode 7b of the capacitor 7, drain electrode 5h and source electrode 5i of the switch transistor 5 and the drain electrode 6h and source electrode 6i of the driving transistor 6. Here, the region in the vicinity of one side edge of the source electrode 6i overlaps the above described region in the vicinity of one side edge of the pixel electrode 8a and are connected to each other.

When the EL panel 1 is a top emission type, the impurity semiconducting films 5f, 5g, 6f, 6g, semiconducting films 5b, 6b are formed and then the source/drain metal layer is deposited and then patterned to form the scanning line 2, voltage supplying line 4, electrode 7b of the capacitor 7, drain electrode 5h and source electrode 5i of the switch transistor 5 and drain electrode 6h and source electrode 6i of the driving transistor 6 and in addition a light reflecting film can be formed in the area where the pixel electrode 8a is formed. The light reflecting film is formed successive to the source electrode 6i. Then, the transparent conducting film such as ITO is deposited and then patterned to form the pixel electrode 8a on the light reflecting film. Here, a region in the vicinity of one side edge of the pixel electrode 8a overlaps a region in the vicinity of one side edge of the source electrode 6i and are connected to each other.

Also, when the EL panel 1 is a top emission type, a light reflecting film (silver or Al, etc.) other than source/drain metal layer can be used. In this case, after the impurity semiconducting films 5f, 5g 6f, 6g and semiconducting films 5b, 6b are formed, the above described other light reflecting film and transparent conducting film such as ITO, etc. are successively deposited and collectively patterned in the shape of the pixel electrode 8a by photolithography. Next, after the source/drain metal layer is deposited, the layer can be patterned to form the scanning line 2, voltage supplying line 4, electrode 7b of the capacitor 7, drain electrode 5h and source electrode 5i of the switch transistor 5, and drain electrode 6h and source electrode 6i of the driving transistor 6. Here, a pixel in the vicinity of one side edge of the source electrode 6i overlaps a region in the vicinity of one side edge of the electrode 8a and are connected to each other. Also, the above described other light reflecting film can be deposited and patterned and then the transparent conducting film such as ITO can be deposited and then patterned. Here, when there is a possibility that the above described other light reflecting film is corroded by the etchant in wet etching of the transparent conducting film, the transparent conducting film can be patterned larger than the above described other light reflecting film so that the transparent conducting film remains not only on an upper face of the above described other light reflecting film but also a side face. Also, when it is not necessary to structure the light reflecting film with the transparent conducting film as part of the pixel electrode 8a, the pixel electrode forming area can be a three layer structure of the above described other light reflecting film, transparent insulating film and transparent conducting film.

Next, as shown in FIG. 7, the insulating film such as silicon nitride is formed by vapor phase epitaxial method so as to cover the switch transistor 5, driving transistor 6, etc., and by patterning the insulating film by photolithography, the interlayer insulating film 12 including the opening 12a where the center section of the pixel electrode 8a is exposed is formed. With the opening 12a, a plurality of contact holes are formed to open external connecting terminal of the scanning line 2, external connecting terminal of each signal line 3 to connect to the data driver in the position on one edge of the EL panel 1, and external connecting terminal of the voltage supplying line 4, which are not shown.

Next, as shown in FIG. 8, a film of photosensitive resin material 13 of polyimide series is formed on the upper face side of the substrate 10 and prebaking is performed.

For example, in the present embodiment, after a film of “Photoneece DW-1000” by Toray Industries, Inc., which is a positive type photosensitive polyimide series resin material, is formed by spin coating, prebaking is performed.

Next, as shown in FIG. 9, after light is exposed on the formed photosensitive resin material 13 using a photomask, developing processing is performed and the grid shaped bank 13 including an opening 13a where the pixel electrode 8a is exposed is formed.

For example, in the present embodiment, after light exposure processing is performed on the formed photosensitive resin material 13 with a predetermined mask pattern, by performing developing processing with tetramethyl ammonium hydroxide (TMAH) aqueous solution, the resin material of the portion corresponding to the opening 13a is eluted to form the opening 13a and the bank 13 is formed.

Incidentally, the TMAH aqueous solution as a developing solution is an alkaline aqueous solution.

Further, the surface of the bank 13 and the pixel electrode 8a exposed to the opening 13a of the bank 13 is neutralized and cleaned.

Here, TMAH used in the present embodiment as the developing solution is easily adsorbed and remains on the surface, etc. of the bank 13 and it is necessary to perform cleaning to remove the TMAH attached to the surface of the formed bank 13 and pixel electrode 8a. Especially, when alkaline TMAH remains on the surface of the bank 13 or pixel electrode 8a, the positive hole injecting layer 8b including molybdenum oxide may be altered. In other words, the TMAH which alters the positive hole injecting layer 8b becomes a factor which prevents light emission, and since the positive hole injecting properties of the altered positive hole injecting layer 8b is worsened, there is a possibility that a problem occurs in the light emission of the EL element 8.

For example, after the exposing processing, first water washing processing is performed on the surface of the formed bank 13 and pixel electrode 8a. After the water washing processing, the surface is rinsed at least once with an organic acid aqueous solution including carboxyl group and sulfo group, etc. showing acidic properties and not including metallic ion as counterion so that the surface is processed to be neutralized or acidic. Also, after processing the residual TMAH with the organic acid aqueous solution, the surface of the bank 13 and the pixel electrode 8a is cleaned again with neutral water or a milder acidic aqueous solution than the organic acid aqueous solution and the organic acid is removed. Incidentally, as organic acid aqueous solution, for example, acetic acid aqueous solution of 0.1 M can be used, however, as long as the solution is acidic, concentration and type of organic acid is not limited to the above, and may be, for example, formic acid, citric acid or oxalic acid.

After processing with organic acid, the substrate 10 with the bank 13 formed is dried and post baking is performed at 180° C. to 250° C. to bake the bank 13.

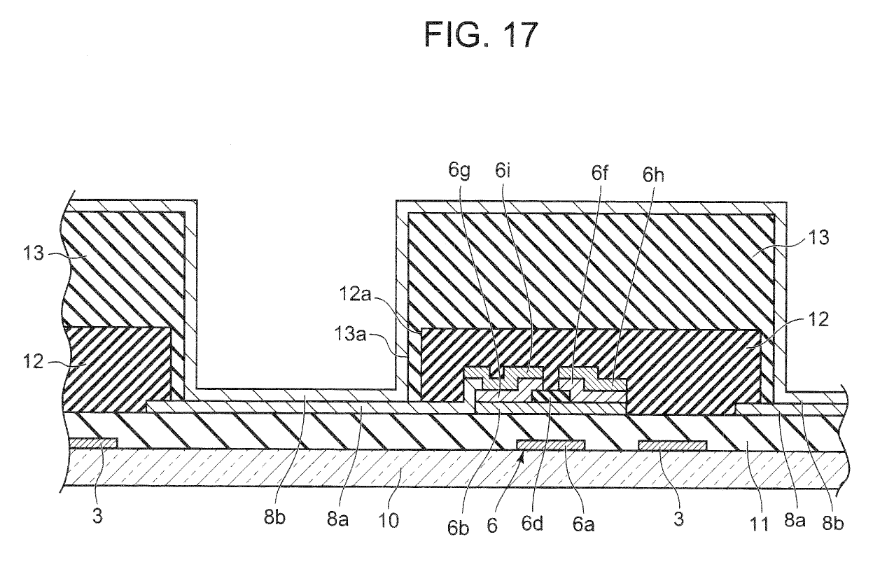

Next, as shown in FIG. 17, using a sputtering method, vacuum evaporation method, etc., a transition metal oxide layer with positive hole injecting properties including, for example, molybdenum oxide is formed to form a positive hole injecting layer 8b on the pixel electrode 8a.

For example, in the present embodiment, a film of molybdenum oxide is formed in a thickness of 30 nm with the evaporation method to form the positive hole injecting layer 8b which covers the pixel electrode 8a and the bank 13.

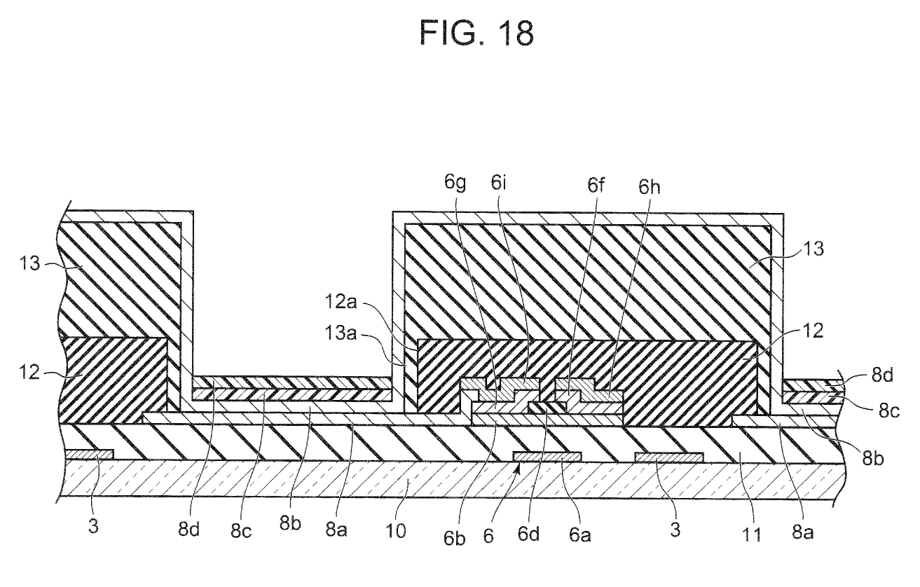

Next, as shown in FIG. 18, a liquid body where organic material including compound of polyfluorene series to compose the interlayer 8c showing electron blocking properties is dissolved or dispersed in an organic solvent such as tetralin, tetramethylbenzene, mesitylene, etc., is applied on the positive hole injecting layer 8b in the opening 13a of the bank 13 with an inkjet method which discharges a plurality of separate droplets or nozzle printing method where a continuous liquid flow flows out and then dried so that the interlayer 8c is laminated and formed on the positive hole injecting layer 8b.

Then, as shown in FIG. 18, a liquid body where organic light emitting material of polyparaphenylene vinylene series or polyfluorene series to compose the light emitting layer 8d is dissolved or dispersed in water or an organic solvent such as tetralin, tetramethylbenzene, mesitylene, etc., is applied on the interlayer 8c in the opening 13a of the bank 13 with an inkjet method or nozzle printing method and then dried to laminate and form the light emitting layer 8d on the interlayer 8c. Incidentally, in the present embodiment, for light emitting testing, a solution where green light emitting material of polyfluorene series is dissolved in xylene is applied on the interlayer 8c in the opening 13a to form the light emitting layer 8d. Also, the light emitting layer 8d can be laminated directly on the positive hole injecting layer 8b without providing the interlayer 8c.

Next, as shown in FIG. 15 the counter electrode 8e is formed on one face on the upper face of the positive hole injecting layer 8b on the bank 13 and on the upper face of the light emitting layer 8d in the opening 13a on the bank 13 and the counter electrode 8e which covers the light emitting layer 8d is formed.

For example, in the present embodiment, after forming Ca with an evaporation method at a thickness of 30 nm, Al with low resistance and a stable nature is formed with an evaporation method at a thickness of 500 nm to form the counter electrode 8e.

Then, by forming the counter electrode 8e, the EL element 8 is formed and the EL panel 1 is manufactured.

As described above, before forming the transition metal oxide layer to form the positive hole injecting layer 8b, by neutralizing and cleaning the surface of the bank 13 and pixel electrode 8a exposed to the opening 13a of the bank 13, the alkaline member such as TMAH which is a factor of preventing light emission which alters the positive hole injecting layer 8b can be removed, and the EL panel 1 including the EL element 8 including the positive hole injecting layer 8b with a good status can be manufactured.

In the EL panel 1 where the surface of the bank 13 and pixel electrode 8a are neutralized and cleaned and the alkaline material which is a factor of preventing light emission is removed, and then the positive hole injecting layer 8b is formed the EL element 8 composing each pixel P suitably emits light.

On the other hand, in the EL panel where the positive hole injecting layer 8b is formed without performing the neutralizing and cleaning to remove the alkaline material which is a factor of preventing light emission, partial areas where the EL element 8 does not emit light in random places on the EL panel, in other words dark spots may appear. This is because, TMAH with an alkaline property alters the positive hole injecting layer 8b including molybdenum oxide and the positive hole injecting property of the altered positive hole injecting layer 8b is worsened, and an EL element 8 which does not emit light appears.

According to the above results, when the EL panel 1 is manufactured including the EL element 8 where the pixel electrode 8a, positive hole injecting layer 8b, light emitting layer 8d and counter electrode 8e are laminated, it can be said that a manufacturing method of the EL panel where the positive hole injecting layer 8b is formed after removing the alkaline material which is a factor of preventing light emission by neutralizing and cleaning the surface of the bank 13 and pixel electrode 8a is a technique which enables manufacturing of an EL panel (light emitting apparatus) with excellent light emitting properties.

Also, the EL panel 1 with the positive hole injecting layer 8b formed after the TMAH is removed based on the above described manufacturing method can be said to be a light emitting apparatus with excellent light emitting properties.

Incidentally, according to the above described embodiment, an example where the light emitting apparatus is applied to an EL panel which is a display apparatus is described, however the present invention is not limited to this, and the present invention can be applied to, for example, a light exposing apparatus, light addressing apparatus and lighting apparatus.

Also, needless to say, other specific details, etc. can be suitably modified.

According to an aspect of the preferred embodiments of the present invention, there is provided a light emitting apparatus including:

a first electrode;

at least one carrier transporting layer on the first electrode;

a second electrode on the carrier transporting layer;

a partition wall formed on an upper face side of a substrate, the partition wall including an opening to be communicated with the first electrode; and

a light emitting protecting layer mediating between the partition wall and the carrier transporting layer.

Preferably, in the light emitting apparatus, the light emitting protecting layer neutralizes or acidifies a factor of preventing light emission caused by the partition wall.

Preferably, in the light emitting apparatus, the light emitting protecting layer is formed from an acidic material.

Preferably, in the light emitting apparatus, the partition wall is formed by hardening a positive type photosensitive polyimide series resin material.

Preferably, in the light emitting apparatus, the partition wall is developed by an alkaline solution.

According to another aspect of the preferred embodiments of the present invention, there is provided a manufacturing method of a light emitting apparatus including a first electrode, at least one carrier transporting layer on the first electrode, and a second electrode on the carrier transporting layer, the method including:

forming a partition wall on an upper face side of a substrate, the partition wall including an opening to be communicated with the first electrode;

forming a light emitting protecting layer to cover at least the partition wall so as to seal a factor of preventing light emission caused by the partition wall; and

forming the carrier transporting layer to cover the first electrode and the light emitting protecting layer.

Preferably, in the manufacturing method of the light emitting apparatus, the step of forming the light emitting protecting layer includes neutralizing or acidifying the factor of preventing light emission caused by the partition wall when a film of material which is to be the light emitting protecting layer is formed.

Preferably, in the manufacturing method of the light emitting apparatus,

the step of forming the partition wall includes developing material which is to be the partition wall with an alkaline solution; and

the step of forming the light emitting protecting layer includes neutralizing or acidifying the alkaline solution remaining on a surface of the partition wall and a surface of the first electrode.

According to another aspect of the preferred embodiments of the present invention, there is provided a manufacturing method of a light emitting apparatus including a light emitting element including a first electrode, at least one carrier transporting layer on the first electrode, and a second electrode on the carrier transporting layer, the method comprising:

forming a partition wall on a substrate, the partition wall including an opening to be communicated with the first electrode;

cleaning a surface of the partition wall and a surface of the first electrode to remove a factor of preventing light emission which occurs in the step of forming the partition wall; and

forming the carrier transporting layer to cover the first electrode and the partition wall.

Preferably, in the manufacturing method of the light emitting apparatus,

the step of forming the partition wall includes exposing material which is to be the partition wall with a predetermined mask pattern and then developing with an alkaline solution; and

the step of cleaning the surfaces includes neutralizing or acidifying the alkaline solution remaining on the surface of the partition wall and the surface of the first electrode with an acidic solution.

Preferably, the manufacturing method of the light emitting apparatus further includes cleaning the partition wall and the first electrode with water or a milder acidic aqueous solution than the acidic solution after the step of neutralizing or acidifying by the acidic solution.

Preferably, the manufacturing method of the light emitting apparatus further includes forming the second electrode on the carrier transporting layer in the opening after forming the carrier transporting layer.

According to another aspect of the preferred embodiments of the present invention, there is provided a light emitting apparatus manufactured by the manufacturing method of the light emitting apparatus.

According to the above described aspects, a light emitting apparatus with excellent light emitting properties can be obtained.

The entire disclosure of Japanese Patent Application No. 2008-225721 filed on Sep. 3, 2008 and Japanese Patent Application No. 2008-229626 filed on Sep. 8, 2008 including specification, claims, drawings and abstract are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A light emitting apparatus comprising:
a first electrode;
at least one carrier transporting layer on the first electrode;
a second electrode on the carrier transporting layer;
a partition wall formed on an upper face side of a substrate, the partition wall including an opening to be communicated with the first electrode; and
a light emitting protecting layer mediating between the partition wall and the carrier transporting layer.

2. The light emitting apparatus according to claim 1, wherein the light emitting protecting layer neutralizes or acidifies a factor of preventing light emission caused by the partition wall.

3. The light emitting apparatus according to claim 1 wherein the light emitting protecting layer is formed from an acidic material.

4. The light emitting apparatus according to claim 1, wherein the partition wall is formed by hardening a positive type photosensitive polyimide series resin material.

5. The light emitting apparatus according to claim 1, wherein the partition wall is developed by an alkaline solution.

6. A manufacturing method of a light emitting apparatus including a first electrode, at least one carrier transporting layer on the first electrode, and a second electrode on the carrier transporting layer, the method comprising:
forming a partition wall on an upper face side of a substrate, the partition wall including an opening to be communicated with the first electrode;
forming a light emitting protecting layer to cover at least the partition wall so as to seal a factor of preventing light emission caused by the partition wall; and
forming the carrier transporting layer to cover the first electrode and the light emitting protecting layer.

7. The manufacturing method of the light emitting apparatus according to claim 6, wherein the step of forming the light emitting protecting layer includes neutralizing or acidifying the factor of preventing light emission caused by the partition wall when a film of material which is to be the light emitting protecting layer is formed.

8. The manufacturing method of the light emitting apparatus according to claim 6, wherein
the step of forming the partition wall includes developing material which is to be the partition wall with an alkaline solution; and
the step of forming the light emitting protecting layer includes neutralizing or acidifying the alkaline solution remaining on a surface of the partition wall and a surface of the first electrode.

9. A manufacturing method of a light emitting apparatus including a light emitting element including a first electrode, at least one carrier transporting layer on the first electrode, and a second electrode on the carrier transporting layer, the method comprising:
forming a partition wall on a substrate, the partition wall including an opening to be communicated with the first electrode;
cleaning a surface of the partition wall and a surface of the first electrode to remove a factor of preventing light emission which occurs in the step of forming the partition wall; and
forming the carrier transporting layer to cover the first electrode and the partition wall.

10. The manufacturing method of the light emitting apparatus according to claim 9, wherein
the step of forming the partition wall includes exposing material which is to be the partition wall with a predetermined mask pattern and then developing with an alkaline solution; and
the step of cleaning the surfaces includes neutralizing or acidifying the alkaline solution remaining on the surface of the partition wall and the surface of the first electrode with an acidic solution.

11. The manufacturing method of the light emitting apparatus according to claim 10, further comprising cleaning the partition wall and the first electrode with water or a milder acidic aqueous solution than the acidic solution after the step of neutralizing or acidifying by the acidic solution.

12. The manufacturing method of the light emitting apparatus according to claim 9, further comprising forming the second electrode on the carrier transporting layer in the opening after forming the carrier transporting layer.

13. A light emitting apparatus manufactured by the manufacturing method of the light emitting apparatus according to claim 9.
